(19) United States
(12) Patent Application Publication
(10) Pub. No.: US 2021/0296597 A1
(43) Pub. Date: Sep. 23, 2021

(54) PHOTOELECTRIC CONVERSION ELEMENT, PHOTOELECTRIC CONVERSION MODULE, ELECTRONIC DEVICE, AND POWER SUPPLY MODULE

(71) Applicant: RICOH COMPANY, LTD., Tokyo (JP)

(72) Inventors: Yuuji TANAKA, Shizuoka (JP); Nozomu TAMOTO, Shizuoka (JP); Naomichi KANEI, Shizuoka (JP); Masato TANAKA, Shizuoka (JP); Tamotsu HORIUCHI, Kyoto (JP)

(21) Appl. No.: 17/203,824

(22) Filed: Mar. 17, 2021

(30) Foreign Application Priority Data
Mar. 23, 2020 (JP) 2020-051185

(51) Int. Cl. H01L 51/00; H01L 51/44

(52) U.S. Cl. CPC H01L 51/0092; H01L 51/441

(57) ABSTRACT

A photoelectric conversion element including: a first electrode; an electron-transporting layer; a hole-transporting layer; and a second electrode. The electron-transporting layer, the hole-transporting layer, and the second electrode are on or above the first electrode. The second electrode includes a charge-collecting layer. The charge-collecting layer includes a conductive nanowire and a conductive polymer that covers at least part of the conductive nanowire and is stacked on the hole-transporting layer.

### CROSS-REFERENCE TO RELATED APPLICATIONS

The present application claims priority under 35 U.S.C. § 119 to Japanese Patent Application No. 2020-051185 filed Mar. 23, 2020. The contents of which are incorporated herein by reference in their entirety.

### BACKGROUND OF THE INVENTION

### Field of the Invention

The present disclosure relates to a photoelectric conversion element, a photoelectric conversion module, an electronic device, and a power supply module.

### Description of the Related Art

In recent years, driving power required in an electronic circuit has become very small, and it has become possible to drive various electronic components such as sensors even with a weak power (ρW order).

Moreover, when a sensor is used, it is expected to be applied to environmental power generation elements as a self-supporting power supply that can generate electricity and can consume the electricity on the spot. Among them, solar cells, which are a kind of photoelectric conversion element, have attracted much interest as an element that can generate electricity anywhere even with a weak light so long as there is light.

Photoelectric conversion elements such as solar cells are required to have output with a low illuminance and durability depending on applications. For example, as transparent electrode materials of the solar cells, conductive transparent materials such as a silver nanowire and conductive transparent polymers have been disclosed (see, for example, Japanese Unexamined Patent Application Publication No. 2017-175019).

### SUMMARY OF THE INVENTION

According to one aspect of the present disclosure, a photoelectric conversion element includes: a first electrode; an electron-transporting layer; a hole-transporting layer; and a second electrode. The electron-transporting layer, the hole-transporting layer, and the second electrode are on or above the first electrode. The second electrode includes a charge-collecting layer, where the charge-collecting layer includes a conductive nanowire and a conductive polymer that covers at least part of the conductive nanowire and is stacked on the hole-transporting layer.

### BRIEF DESCRIPTION OF THE DRAWINGS

FIG. 1 is a schematic view presenting one example of a photoelectric conversion element of the present disclosure;

FIG. 2 is a schematic view presenting another example of a photoelectric conversion element of the present disclosure;

FIG. 3 is a schematic view presenting one example of a photoelectric conversion element of Comparative Example 3;

FIG. 4 is a scanning electron microscope (SEM) photograph obtained by observing the surface of a second electrode in a photoelectric conversion element of Example 1;

FIG. 5 is a block diagram of a mouse for a personal computer as one example of an electronic device of the present disclosure;

FIG. 6 is a schematic external view presenting one example of the mouse presented in FIG. 5;

FIG. 7 is a block diagram of a keyboard for a personal computer as one example of an electronic device of the present disclosure;

FIG. 8 is a schematic external view presenting one example of the keyboard presented in FIG. 7;

FIG. 9 is a schematic external view presenting another example of the keyboard presented in FIG. 7;

FIG. 10 is a block diagram of a sensor as one example of an electronic device of the present disclosure;

FIG. 11 is a block diagram of a turntable as one example of an electronic device of the present disclosure;

FIG. 12 is a block diagram presenting one example of an electronic device of the present disclosure;

FIG. 13 is a block diagram presenting one example where a power supply integrated circuit (IC) is further incorporated into the electronic device presented in FIG. 12;

FIG. 14 is a block diagram presenting one example where an electricity storage device is further incorporated into the electronic device presented in FIG. 13;

FIG. 15 is a block diagram presenting one example of a power supply module of the present disclosure; and

FIG. 16 is a block diagram presenting one example where an electricity storage device is further incorporated into the power supply module presented in FIG. 15.

### DETAILED DESCRIPTION OF THE INVENTION

### (Photoelectric Conversion Element)

A photoelectric conversion element of the present disclosure includes a first electrode, an electron-transporting layer, a hole-transporting layer, and a second electrode. The electron-transporting layer, the hole-transporting layer, and the second electrode are on or above the first electrode. The photoelectric conversion element of the present disclosure further includes other layers if necessary.

The second electrode includes a charge-collecting layer, where the charge-collecting layer includes a conductive nanowire and a conductive polymer that covers at least part of the conductive nanowire and is stacked on the hole-transporting layer. The conductive nanowire is preferably a silver nanowire in terms of conductivity.

In the charge-collecting layer, the at least part of the conductive nanowire is preferably embedded in the conductive polymer.

The present disclosure can provide a photoelectric conversion element that can prevent a conductive nanowire from being peeled and can obtain a high output.

According to the present disclosure, it is possible to provide a photoelectric conversion element that can prevent a conductive nanowire from being peeled and can obtain a high output.

In the conventional techniques, a silver nanowire and a conductive polymer are simply used in combination, and the silver nanowire is peeled from the second electrode over time. As a result, a problem that the second electrode is destroyed occurs.

In the present disclosure, the second electrode includes a charge-collecting layer, where the charge-collecting layer includes a conductive nanowire and a conductive polymer that covers at least part of the conductive nanowire and is stacked on the hole-transporting layer; and the at least part of the conductive nanowire is covered with the conductive polymer and gaps between the adjacent conductive nanowires are filled with the conductive polymer. Therefore, the conductive nanowire can be prevented from being peeled from the second electrode, which improves light durability. In addition, gaps between conductive nanowires other than the gaps existing directly under the conductive nanowire are filled with the conductive polymer. Therefore, charges of the gaps between the conductive nanowires can be also collected from the hole-transporting layer, to improve the output.

### <Second Electrode>

The second electrode includes a charge-collecting layer, where the charge-collecting layer includes a conductive nanowire and a conductive polymer that covers at least part of the conductive nanowire and is stacked on the hole-transporting layer. Moreover, 50% or more of the whole conductive nanowire is preferably covered with the conductive polymer, and all conductive nanowire may be covered with the conductive polymer.

The at least part of the conductive nanowire is preferably embedded in the conductive polymer, 50% or more of the whole conductive nanowire is preferably embedded in the conductive polymer, and all conductive nanowire may be embedded in the conductive polymer.

A conductive nanowire layer including a conductive nanowire is formed on a hole-transporting layer, and a conductive polymer is provided thereon so that the conductive polymer covers at least part of the conductive nanowire and is stacked on the hole-transporting layer, to thereby form a charge-collecting layer.

### —Conductive Nanowire—

The conductive nanowire, which has a cross-sectional diameter of less than 1 μm and an aspect ratio (major axis length/diameter) of 10 or more, is a wire-shaped metal structure having a nano-level cross-sectional diameter.

A diameter of the conductive nanowire is preferably 5 nm or more but 250 nm or less, more preferably 10 nm or more but 150 nm or less. When the diameter falls within the ranges, the coating film is excellent in transparency.

A major axis length of the conductive nanowire is preferably 0.5 μm or more but 500 μm or less, more preferably 2.5 μm or more but 100 μm or less. When the major axis length falls within the ranges, dispersibility of the conductive nanowire is excellent, and conductivity and transparency are excellent in the case of a transparent conductive film.

Examples of the conductive nanowire include: metal-coated organic fibers and inorganic fibers; conductive metal oxide fibers; metal nanowires; carbon fibers; and carbon nanotube. Among them, metal nanowires are preferable because they satisfy the conductivity.

A metal composition of the metal nanowire is not particularly limited and may be appropriately selected depending on the intended purpose. The metal composition of the metal nanowire can be formed of one kind or a plurality kinds of metal(s) such as noble metal element(s) or base metal element(s). However, the metal nanowire preferably includes at least one kind of metal that belongs to the group consisting of the noble metal (e.g., gold, platinum, silver, palladium, rhodium, iridium, ruthenium, and osmium), iron, cobalt, copper, and tin. The metal nanowire particularly preferably includes silver in terms of conductivity.

Therefore, the conductive nanowire is particularly preferably a silver nanowire.

The silver nanowire as the conductive nanowire is not particularly limited, and one obtained by the known production method can be used. In the present disclosure, it is preferable to use a silver nanowire obtained by a production method that includes a step of allowing a silver compound to react in polyol at from 25° C. through 180° C. using, as a wire growth controlling agent, an N-substituted acrylamide-containing polymer.

The silver nanowire layer is formed by providing a silver nanowire dispersion liquid on the hole-transporting layer.

The silver nanowire dispersion liquid includes a silver nanowire, a dispersion medium, and other components.

Examples of the dispersion medium include water and alcohols. Examples of the alcohols include methanol, ethanol, 1-propanol, 2-propanol, 1-butanol, 2-butanol, 2-methylpropanol, 1,1-dimethylethanol, and cyclohexanol. These may be used alone or in combination.

If necessary, the silver nanowire dispersion liquid can include, as the other components, various additives such as a surfactant, a polymerizable compound, an antioxidant, a sulfurization preventing agent, a corrosion preventing agent, a viscosity modifier, and a preservative.

The silver nanowire layer can be formed by the known coating method by using the silver nanowire dispersion liquid. Examples of the coating method include the spin-coating method, the slit coating method, the dip coating method, the blade coating method, the bar coating method, the spray method, the relief printing method, the intaglio printing method, the screen printing method, the lithographic printing method, the dispensing method, and the inkjet method.

### —Conductive Polymer—

The conductive polymer is not particularly limited and may be appropriately selected depending on the intended purpose. Examples of the conductive polymer include polythiophene or derivatives thereof, polyaniline or derivatives thereof, polypyrrole or derivatives thereof, polyacetylene or derivatives thereof, polycarbazole or derivatives thereof, polyvinylpyridine or derivatives thereof, poly(n-vinylcarbazole) or derivatives thereof, polyfluorene or derivatives thereof, polyphenylene or derivatives thereof, poly(p-phenylenevinylene) or derivatives thereof, poly(pyridine vinylene) or derivatives thereof, polyquinoxaline or derivatives thereof, polyquinoline or derivatives thereof, polyoxadiazole derivatives, polybathophenanthroline derivatives, polytriazole derivatives, and compounds obtained by appropriately substituting these polymers with a substituent such as an amine group, a hydroxy group, a nitrile group, or a carbonyl group. These may be used alone or in combination. Among them, polythiophene or derivatives thereof, polyaniline or derivatives thereof, and polypyrrole or derivatives thereof are preferable because they have a high conductivity.

The charge-collecting layer can be formed by coating a conductive polymer dispersion liquid prepared by the known method on the conductive nanowire layer by the known coating method. Examples of the coating method include the spin-coating method, the slit coating method, the dip coating method, the blade coating method, the bar coating method, the spray method, the relief printing method, the intaglio printing method, the screen printing method, the lithographic printing method, the dispensing method, and the inkjet method.

An average thickness of the charge-collecting layer is not particularly limited and may be appropriately selected depending on the intended purpose. The average thickness thereof is preferably 0.02 am or more but 0.2 μm or less, more preferably 0.05 μm or more but 0.1 μm or less.

Preferably, in the charge-collecting layer, the conductive polymer covers the conductive nanowire, and can be filled in gaps between the adjacent conductive nanowires. An amount of the conductive polymer is preferably smaller than an amount of the conductive nanowire in order to obtain a high conductivity.

A volume ratio (A:B) between an amount A of the conductive nanowire in the charge-collecting layer and an amount B of the conductive polymer in the charge-collecting layer is preferably from 1:1 through 1:4.

When the volume ratio (A:B) is from 1:1 through 1:4, an excellent light durability and a high output can be obtained.

The second electrode preferably has translucency. Having transparency means that a light transmittance of the second electrode is 80% or more. The light transmittance can be measured by a general ultraviolet and visible spectrophotometer.

### <First Substrate and Second Substrate>

A shape, structure, and size of the substrate are not particularly limited and may be appropriately selected depending on the intended purpose.

A material of the substrate is preferably a material having transparency and an insulation property. Examples of the material include glass, plastic films, and ceramics. Among them, a material having heat resistance against a firing temperature is preferable when the firing step is performed to form the electron-transporting layer. Moreover, the substrate is preferably a substrate having flexibility.

The substrate may be disposed on an outermost part at a side of the first electrode of the photoelectric conversion element, may be disposed on an outermost part at a side of the second electrode of the photoelectric conversion element, or may be disposed on both the outermost part at the side of the first electrode of the photoelectric conversion element and the outermost part at the side of the second electrode of the photoelectric conversion element.

Hereinafter, the substrate disposed on the outermost part at the side of the first electrode is referred to as a first substrate, and the substrate disposed on the outermost part at the side of the second electrode is referred to as a second substrate.

An average thickness of the substrate is not particularly limited and may be appropriately selected depending on the intended purpose. The average thickness of the substrate is, for example, 50 μm or more but 5 mm or less.

### <First Electrode>

A shape and size of the first electrode are not particularly limited and may be appropriately selected depending on the intended purpose.

A structure of the first electrode is not particularly limited and may be appropriately selected depending on the intended purpose. The structure of the first electrode may be a single layer structure or may be a structure where a plurality of materials are stacked.

A material of the first electrode is not particularly limited and may be appropriately selected depending on the intended purpose, so long as it has conductivity. Examples of the material include transparent conductive metal oxides, carbon, and metals.

Examples of the transparent conductive metal oxide include indium-tin oxide (referred to as “ITO” hereinafter), fluorine-doped tin oxide (referred to as “FTO” hereinafter), antimony-doped tin oxide (referred to as “ATO” hereinafter), niobium-doped tin oxide (referred to as “NTO” hereinafter), aluminum-doped zinc oxide (referred to as AZO” hereinafter), indium-zinc oxide, and niobium-titanium oxide.

Examples of the carbon include carbon black, carbon nanotube, graphene, and fullerene.

Examples of the metal include gold, silver, aluminum, nickel, indium, tantalum, and titanium.

These may be used alone or in combination. Among them, a transparent conductive metal oxide having high transparency is preferable, and ITO, FTO, ATO, NTO, and AZO are more preferable.

An average thickness of the first electrode is not particularly limited and may be appropriately selected depending on the intended purpose. The average thickness of the first electrode is preferably 5 nm or more but 100 μm or less, more preferably 50 nm or more but 10 μm or less. When a material of the first electrode is carbon or a metal, the average thickness of the first electrode is preferably an enough average thickness to obtain translucency.

The first electrode can be formed by known methods such as the sputtering method, the vapor deposition method, and the spray method.

The first electrode is preferably formed on the substrate. An integrated commercially available product where the first electrode is formed on the substrate in advance can be used.

Examples of the integrated commercially available product include FTO-coated glass, ITO-coated glass, zinc oxide, aluminum-coated glass, FTO-coated transparent plastic films, and ITO-coated transparent plastic films. Examples of other integrated commercially available products include: a glass substrate provided with a transparent electrode where tin oxide or indium oxide is doped with a cation or an anion having a different atomic value; and a glass substrate provided with a metal electrode having such a structure that allows light in the form of a mesh or stripes to pass.

These may be used alone, or two or more products may be used in combination as a mixed product or a laminate. Moreover, a metal lead wire may be used in combination in order to decrease an electric resistance value.

In order to produce a photoelectric conversion module that will be described hereinafter, an electrode of an integrated commercially available product may be appropriately processed to produce a substrate on which a plurality of first electrodes are formed.

A material of the metal lead wire is, for example, aluminum, copper, silver, gold, platinum, and nickel.

The metal lead wire can be used in combination by forming it on the substrate through, for example, vapor deposition, sputtering, or pressure bonding, and disposing a layer of ITO or FTO thereon or disposing it on ITO or FTO.

### <Hole Blocking Layer>

In order to prevent a decrease in electric power, which is caused when a hole-transporting layer contacts an electrode to recombine holes in the hole-transporting layer and electrons on the surface of the electrode (i.e., reverse electron transfer), the hole blocking layer is provided. An effect of the hole blocking layer is particularly significant in a solid-dye-sensitization-type solar cell. The reason for this is attributed to the fact that the solid-dye-sensitization-type solar cell containing, for example, an organic hole-transporting material has a rapider rate of recombination (reverse electron transfer) of holes in the hole-transporting material and electrons on the surface of the electrode compared to a wet-dye-sensitization-type solar cell containing, for example, an electrolytic solution.

The hole blocking layer is disposed on, for example, the first electrode.

A material of the hole blocking layer is not particularly limited and may be appropriately selected depending on the intended purpose, so long as it is transparent to a visible light and is an electron-transporting material. Examples of the material include titanium oxide, niobium oxide, magnesium oxide, aluminum oxide, zinc oxide, tungsten oxide, and tin oxide. Among them, titanium oxide is more preferable. These may be used alone or in combination.

A film formation method of the hole blocking layer is not particularly limited and may be appropriately selected depending on the intended purpose. In order to prevent electric current loss with indoor light, a high internal resistance is required, and the film formation method is also important. Generally, examples thereof include a sol-gel method that is a wet film formation method. However, such a method cannot achieve a high film density, and cannot sufficiently prevent electric current loss. Therefore, the film formation method is more preferably a dry film formation method such as a sputtering method, and such a method can achieve a sufficiently high film density, to prevent electric current loss.

An average thickness of the hole blocking layer is not particularly limited and may be appropriately selected depending on the intended purpose. In terms of a transmittance and prevention of reverse electron transfer, the average thickness of the hole blocking layer is preferably 5 nm or more but 1,000 nm or less, more preferably 500 nm or more but 700 nm or less in the case of the wet film formation method, and more preferably 10 nm or more but 30 nm or less in the case of the dry film formation method.

### <Photoelectric Conversion Layer>

The photoelectric conversion layer includes an electron-transporting layer and a hole-transporting layer, and further includes other members if necessary.

### <<Electron-Transporting Layer>>

The electron-transporting layer includes an electron-transporting semiconductor.

The electron-transporting layer preferably includes an electron-transporting semiconductor including a photosensitization compound adsorbed on a surface thereof.

The electron-transporting layer is disposed on, for example, the hole blocking layer.

The electron-transporting layer may be a single layer or a multilayer.

As the electron-transporting semiconductor, an electron-transporting semiconductor particle is preferably used.

In the case of a multilayer, a dispersion liquid of semiconductor particles different in particle diameters may be coated to form a multilayer, or different kinds of semiconductors or coating layers having composition different in a resin and an additive may be coated to form a multilayer.

Note that, when a film thickness obtained after one coating is insufficient, the multilayer coating is an effective means.

Generally, as an average thickness of the electron-transporting layer increases, an amount of the born photosensitization material per a unit projected area also increases. Therefore, a light trapping rate increases, but a diffusion length of injected electrons also increases, which results in a large loss due to recombination of electric charges. Therefore, the average thickness of the electron-transporting layer is preferably 100 nm or more but 100 am or less.

The electron-transporting semiconductor is not particularly limited and may be appropriately selected depending on the intended purpose. Examples of the electron-transporting semiconductor include: simple substance semiconductors such as silicon and germanium; compound semiconductors such as chalcogenides of metal; and compounds having a perovskite structure. These may be used alone or in combination.

Examples of the chalcogenides of metal include: oxides of, for example, titanium, tin, zinc, iron, tungsten, zirconium, hafnium, strontium, indium, cerium, yttrium, lanthanum, vanadium, niobium, and tantalum; sulfides of, for example, cadmium, zinc, lead, silver, antimony, and bismuth; selenides of, for example, cadmium and lead; and tellurium compounds of, for example, cadmium.

Examples of the other compound semiconductors include: phosphides of zinc, gallium, indium, and cadmium; gallium arsenide; copper-indium-selenide, and copper-indium-sulfide.

Examples of the compound having a perovskite structure include strontium titanate, calcium titanate, sodium titanate, barium titanate, and potassium niobate.

Among the electron-transporting semiconductors, oxide semiconductors are preferable, titanium oxide, zinc oxide, tin oxide, and niobium oxide are more preferable, and titanium oxide is particularly preferable.

A crystal type of the electron-transporting semiconductor is not particularly limited and may be appropriately selected depending on the intended purpose. The crystal type may be a single crystal, polycrystalline, or amorphous.

A size of the semiconductor particle is not particularly limited and may be appropriately selected depending on the intended purpose. An average particle diameter of primary particles is preferably 1 nm or more but 100 nm or less, more preferably 5 nm or more but 50 nm or less.

Moreover, an effect of diffusing incident light achieved by mixing or stacking a semiconductor particle having a larger average particle diameter may improve efficiency. In this case, an average particle diameter of the semiconductor particle is preferably 50 nm or more but 500 nm or less.

A production method of the electron-transporting layer is not particularly limited and may be appropriately selected depending on the intended purpose. Examples of the production method include a method such as sputtering where a thin film is formed in vacuum, and a wet film formation method. Among them, in terms of production cost, it is preferable to use a wet film formation method, and it is particularly preferable to use a method where paste obtained by dispersing particles or sol of a semiconductor is prepared, and then the paste is coated onto the hole blocking layer.

When the wet film formation method is used, a coating method is not particularly limited and may be appropriately selected depending on the intended purpose. Examples of the coating method include the dip method, the spray method, the wire bar method, the spin-coating method, the roller coating method, the blade coating method, and the gravure coating method. Examples of a wet printing method include relief printing, offset printing, gravure printing, intaglio printing, rubber plate printing, and screen printing.

When the dispersion liquid of the semiconductor particle is prepared by using mechanical pulverization or a mill, at least a semiconductor particle alone or a mixture of a semiconductor particle and a resin is dispersed in water or an organic solvent to prepare the dispersion liquid.

The resin is not particularly limited and may be appropriately selected depending on the intended purpose. Examples of the resin include polymers or copolymers of vinyl compounds (e.g., styrene, vinyl acetate, acrylic acid ester, and methacrylic acid ester), silicone resins, phenoxy resins, polysulfone resins, polyvinyl butyral resins, polyvinyl formal resins, polyester resins, cellulose ester resins, cellulose ether resins, urethane resins, phenol resins, epoxy resins, polycarbonate resins, polyarylate resins, polyamide resins, and polyimide resins. These may be used alone or in combination.

Examples of the solvent include water, alcohol solvents, ketone solvents, ester solvents, ether solvents, amide solvents, halogenated hydrocarbon solvents, and hydrocarbon solvents.

Examples of the alcohol solvent include methanol, ethanol, isopropyl alcohol, and α-terpineol.

Examples of the ketone solvent include acetone, methyl ethyl ketone, and methyl isobutyl ketone.

Examples of the ester solvent include ethyl formate, ethyl acetate, and n-butyl acetate.

Examples of the ether solvent include diethyl ether, dimethoxy ethane, tetrahydrofuran, dioxolane, and dioxane.

Examples of the amide solvent include N,N-dimethylformamide, N,N-dimethylacetamide, and N-methyl-2-pyrrolidone.

Examples of the halogenated hydrocarbon solvent include dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene.

Examples of the hydrocarbon solvent include n-pentane, n-hexane, n-octane, 1,5-hexadiene, cyclohexane, methylcyclohexane, cyclohexadiene, benzene, toluene, o-xylene, m-xylene, p-xylene, ethylbenzene, and cumene.

These may be used alone or in combination.

To the dispersion liquid of the semiconductor particle or the paste of the semiconductor particle obtained by, for example, the sol-gel method, an acid, a surfactant, or a chelating agent may be added in order to prevent re-aggregation of the particles.

Examples of the acid include hydrochloric acid, nitric acid, and acetic acid.

Examples of the surfactant include polyoxyethylene octylphenyl ether.

Examples of the chelating agent include acetyl acetone, 2-aminoethanol, and ethylene diamine.

Moreover, addition of a thickener is also an effective means for the purpose of improving a film formation property.

Examples of the thickener include polyethylene glycol, polyvinyl alcohol, and ethyl cellulose.

In order to electronically contact particles with each other after the coating to improve strength of a film and adhesiveness to a substrate, the semiconductor particle is preferably subjected to firing, irradiation of microwave, irradiation of electron rays, and irradiation of laser light. These treatments may be performed alone or in combination.

When the firing is performed, the firing temperature is not particularly limited and may be appropriately selected depending on the intended purpose. When the firing temperature is increased too much, a resistance of the substrate may be increased or melting may occur. Therefore, the firing temperature is preferably 30° C. or more but 700° C. or less, more preferably 100° C. or more but 600° C. or less. The firing time is not particularly limited and may be appropriately selected depending on the intended purpose, but is preferably 10 minutes or more but 10 hours or less.

The microwave may be emitted from a side at which the electron-transporting layer is formed, or may be emitted from the back side. The irradiation time of the microwave is not particularly limited and may be appropriately selected depending on the intended purpose. The irradiation time of the microwave is preferably one hour or shorter.

After firing, for example, chemical plating using an aqueous solution of titanium tetrachloride or a mixed solution with an organic solvent, or electrochemical plating using an aqueous solution of titanium trichloride may be performed in order to increase a surface area of the semiconductor particle or enhance an electron injection efficiency to the semiconductor particle from the photosensitization compound.

A stacked film, which is obtained by, for example, firing the semiconductor particle having a diameter of several tens of nanometers, can form a porous state. Such a nanoporous structure has an extremely high surface area, and the surface area can be represented by using a roughness factor.

The roughness factor is a numerical value representing an actual area of the inner sides of pores relative to an area of the semiconductor particles coated onto the substrate. Therefore, the roughness factor is preferably larger. However, in terms of a relationship with a thickness of the electron-transporting layer, the roughness factor is preferably 20 or more.

### <<Photosensitization Compound>>

In the present disclosure, the photosensitization compound is preferably adsorbed on the surface of the electron-transporting semiconductor of the electron-transporting layer in order to further improve the conversion efficiency.

The photosensitization compound is not particularly limited and may be appropriately selected depending on the intended purpose so long as the photosensitization compound is a compound photoexcited by excitation light to be used. Examples of the photosensitization compound include: metal complex compounds described in, for example, Japanese Translation of PCT International Application Publication No. 7-500630, Japanese Unexamined Patent Application Publication No. 10-233238, Japanese Unexamined Patent Application Publication No. 2000-26487, Japanese Unexamined Patent Application Publication No. 2000-323191, and Japanese Unexamined Patent Application Publication No. 2001-59062; coumarine compounds described in, for example, Japanese Unexamined Patent Application Publication No. 10-93118, Japanese Unexamined Patent Application Publication No. 2002-164089, Japanese Unexamined Patent Application Publication No. 2004-95450, and J. Phys. Chem. C, 7224, Vol. 111 (2007); polyene compounds described in, for example, Japanese Unexamined Patent Application Publication No. 2004-95450 and Chem. Commun., 4887 (2007); indoline compounds described in, for example, Japanese Unexamined Patent Application Publication No. 2003-264010, Japanese Unexamined Patent Application Publication No. 2004-63274, Japanese Unexamined Patent Application Publication No. 2004-115636, Japanese Unexamined Patent Application Publication No. 2004-200068, Japanese Unexamined Patent Application Publication No. 2004-235052, J. Am. Chem. Soc., 12218, Vol. 126 (2004), Chem. Commun., 3036 (2003), and Angew. Chem. Int. Ed., 1923, Vol. 47 (2008); thiophene compounds described in, for example, J. Am. Chem. Soc., 16701, Vol. 128 (2006) and J. Am. Chem. Soc., 14256, Vol. 128 (2006); cyanine dyes described in, for example, Japanese Unexamined Patent Application Publication No. 11-86916, Japanese Unexamined Patent Application Publication No. 11-214730, Japanese Unexamined Patent Application Publication No. 2000-106224, Japanese Unexamined Patent Application Publication No. 2001-76773, and Japanese Unexamined Patent Application Publication No. 2003-7359; merocyanine dyes described in, for example, Japanese Unexamined Patent Application Publication No. 11-214731, Japanese Unexamined Patent Application Publication No. 11-238905, Japanese Unexamined Patent Application Publication No. 2001-52766, Japanese Unexamined Patent Application Publication No. 2001-76775, and Japanese Unexamined Patent Application Publication No. 2003-7360; 9-arylxanthene compounds described in, for example, Japanese Unexamined Patent Application Publication No. 10-92477, Japanese Unexamined Patent Application Publication No. 11-273754, Japanese Unexamined Patent Application Publication No. 11-273755, and Japanese Unexamined Patent Application Publication No. 2003-31273; triarylmethane compounds described in, for example, Japanese Unexamined Patent Application Publication No. 10-93118 and Japanese Unexamined Patent Application Publication No. 2003-31273; and phthalocyanine compounds and porphyrin compounds described in, for example, Japanese Unexamined Patent Application Publication No. 9-199744, Japanese Unexamined Patent Application Publication No. 10-233238, Japanese Unexamined Patent Application Publication No. 11-204821, Japanese Unexamined Patent Application Publication No. 11-265738, J. Phys. Chem., 2342, Vol. 91 (1987), J. Phys. Chem. B, 6272, Vol. 97 (1993), Electroanal. Chem., 31, Vol. 537 (2002), Japanese Unexamined Patent Application Publication No. 2006-032260, J. Porphyrins Phthalocyanines, 230, Vol. 3 (1999), Angew. Chem. Int. Ed., 373, Vol. 46 (2007), and Langmuir, 5436, Vol. 24 (2008). Among them, metal complex compounds, coumarine compounds, polyene compounds, indoline compounds, and thiophene compounds are preferable, compounds expressed by the following Structural Formula (1), the following Structural Formula (2), and the following Structural Formula (3) (available from Mitsubishi Paper Mills Limited) are more preferable. These photosensitization compounds may be used alone or in combination.

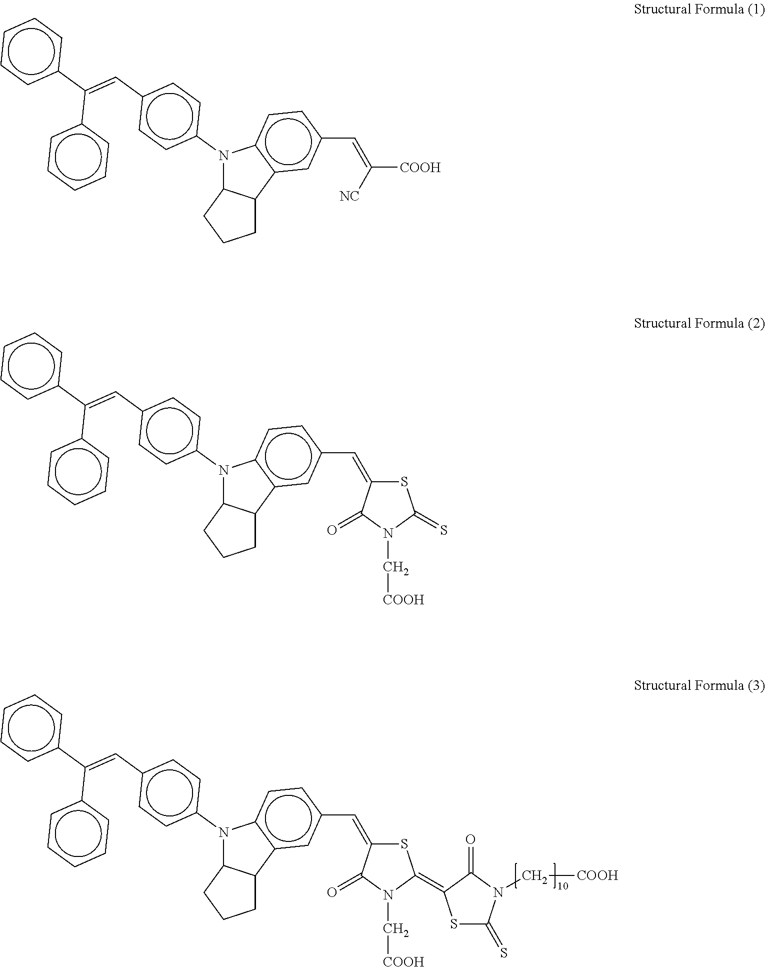

A compound including the following General Formula (1) is more preferable.

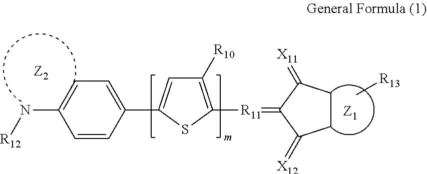

In the General Formula (1), X₁₁ and X₁₂ each independently represent an oxygen atom, a sulfur atom, or a selenium atom.

R₁₀ represents a hydrogen atom or a hexyl group. R₁₁ represents a methine group that may have a substituent. Specific examples of the substituent include an aryl group (e.g., a phenyl group and a naphthyl group) and a heterocycle (e.g., a thienyl group and a furyl group).

R₁₂ represents an alkyl group that may have a substituent, an aryl group that may have a substituent, or a heterocyclic group that may have a substituent. Examples of the alkyl group include a methyl group, an ethyl group, a 2-propyl group, and a 2-ethylhexyl group. Examples of the aryl group and the heterocyclic group include the groups exemplified above.

R₁₃ represents an acid group such as carboxylic acid, sulfonic acid, phosphonic acid, boronic acid, or phenols. The number of R₁₃ may be one or more.

Z₁ and Z₂ each independently represent a substituent that forms a cyclic structure. Examples of Z₁ include condensed hydrocarbon-based compounds (e.g., a benzene ring and a naphthalene ring) and heterocycles (e.g., a thiophene ring and a furan ring) each of which may have a substituent. Specific examples of the substituent include the alkyl groups and the alkoxy groups (e.g., a methoxy group, an ethoxy group, and a 2-isopropoxy group) described above. Examples of Z₂ include the following (A-1) to (A-22).

m represents an integer of from 0 through 2.

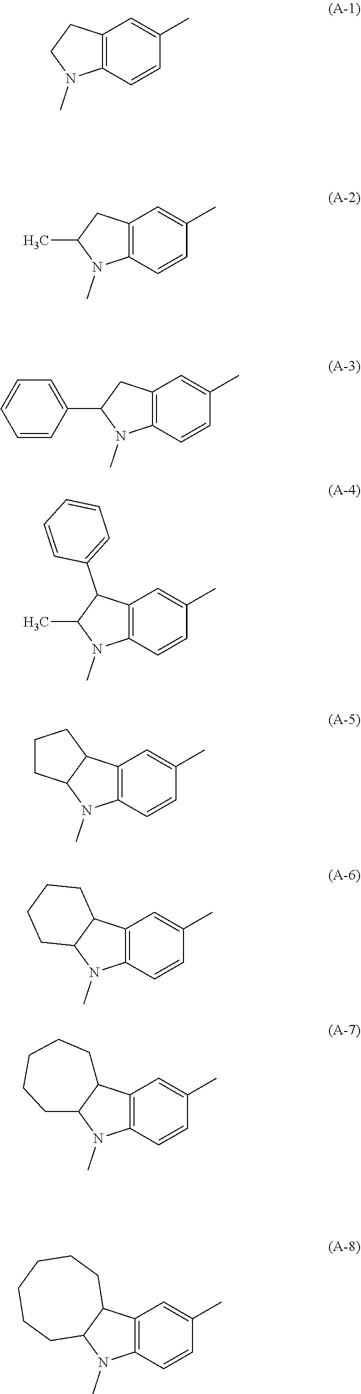

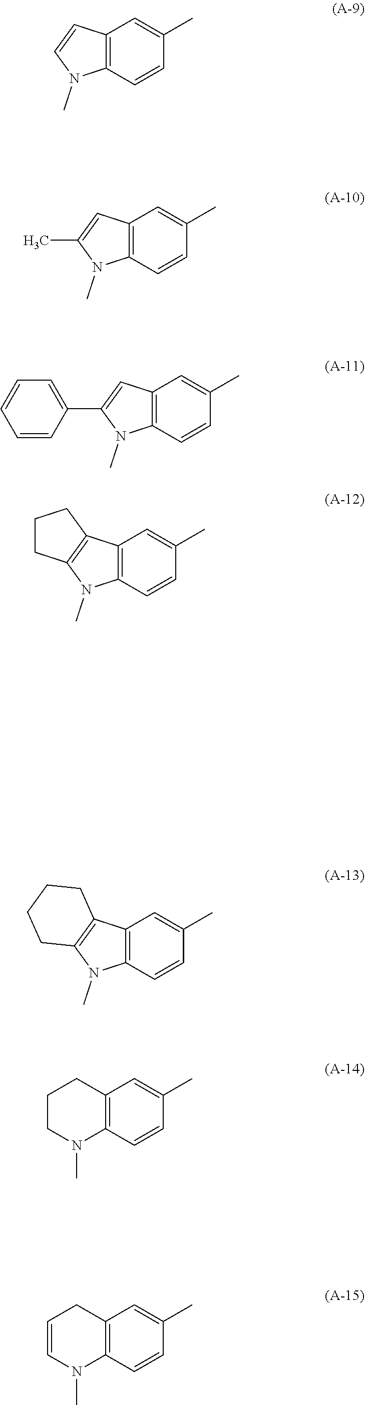

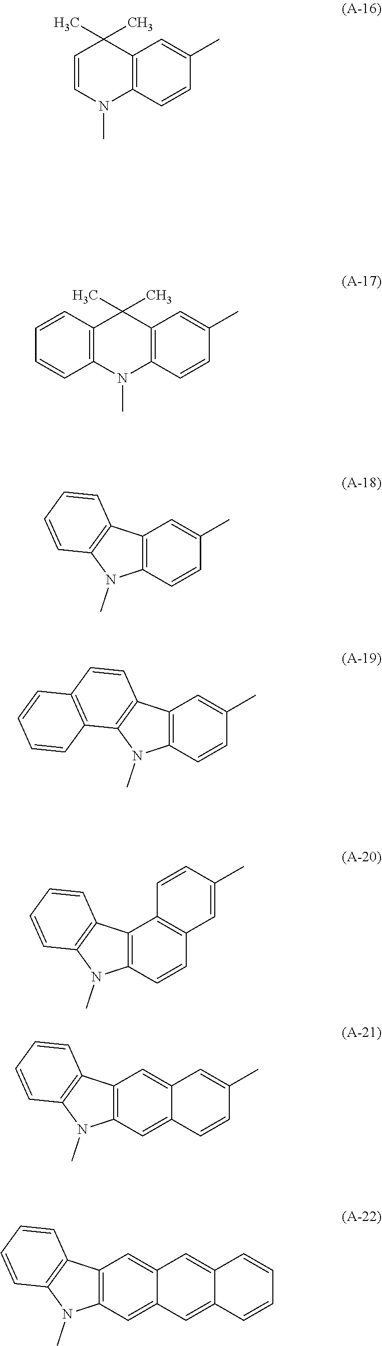

Specific examples of the photosensitization compound including the General Formula (1) include, but are not limited to, the following (B-1) to (B-40).

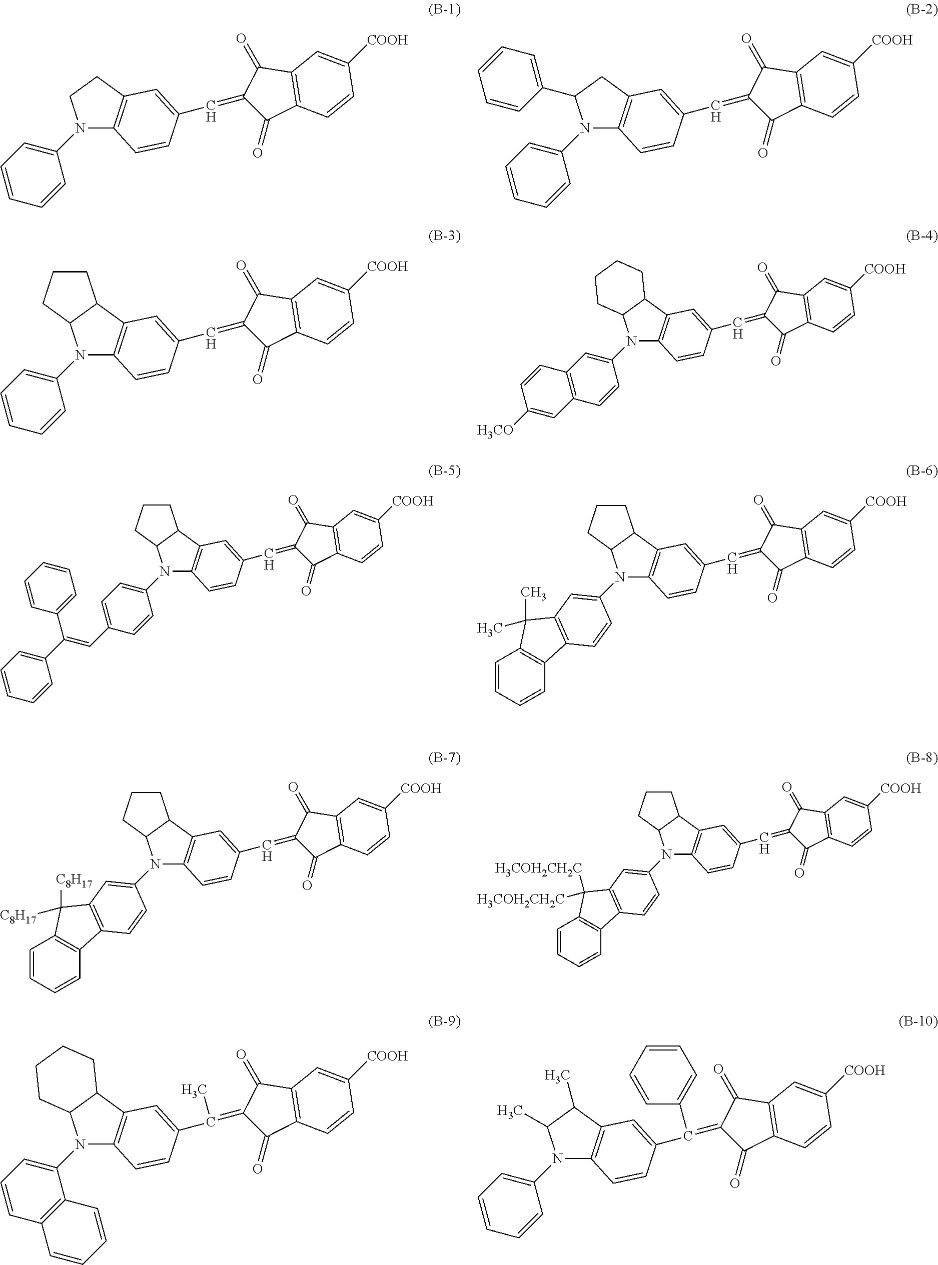

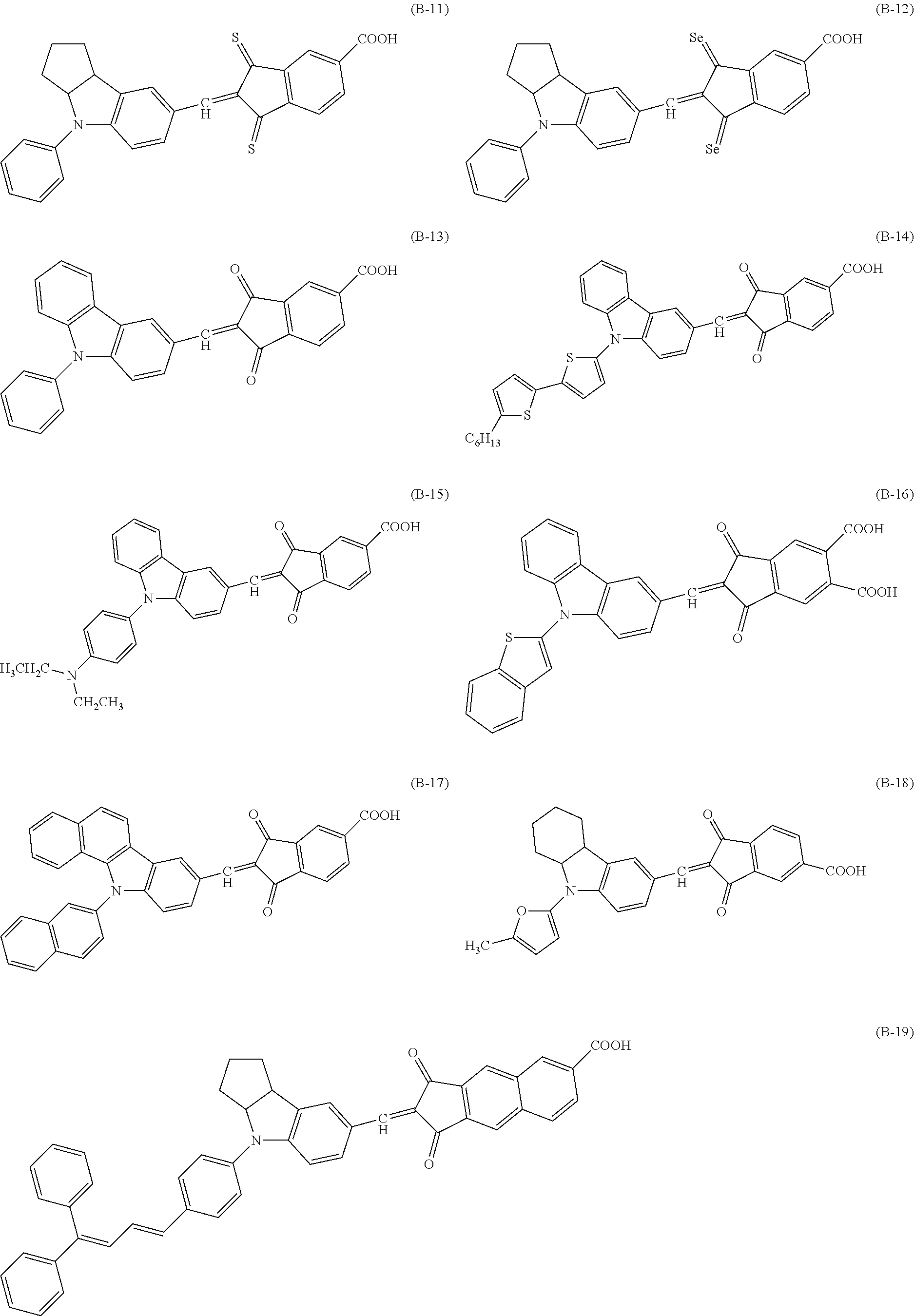

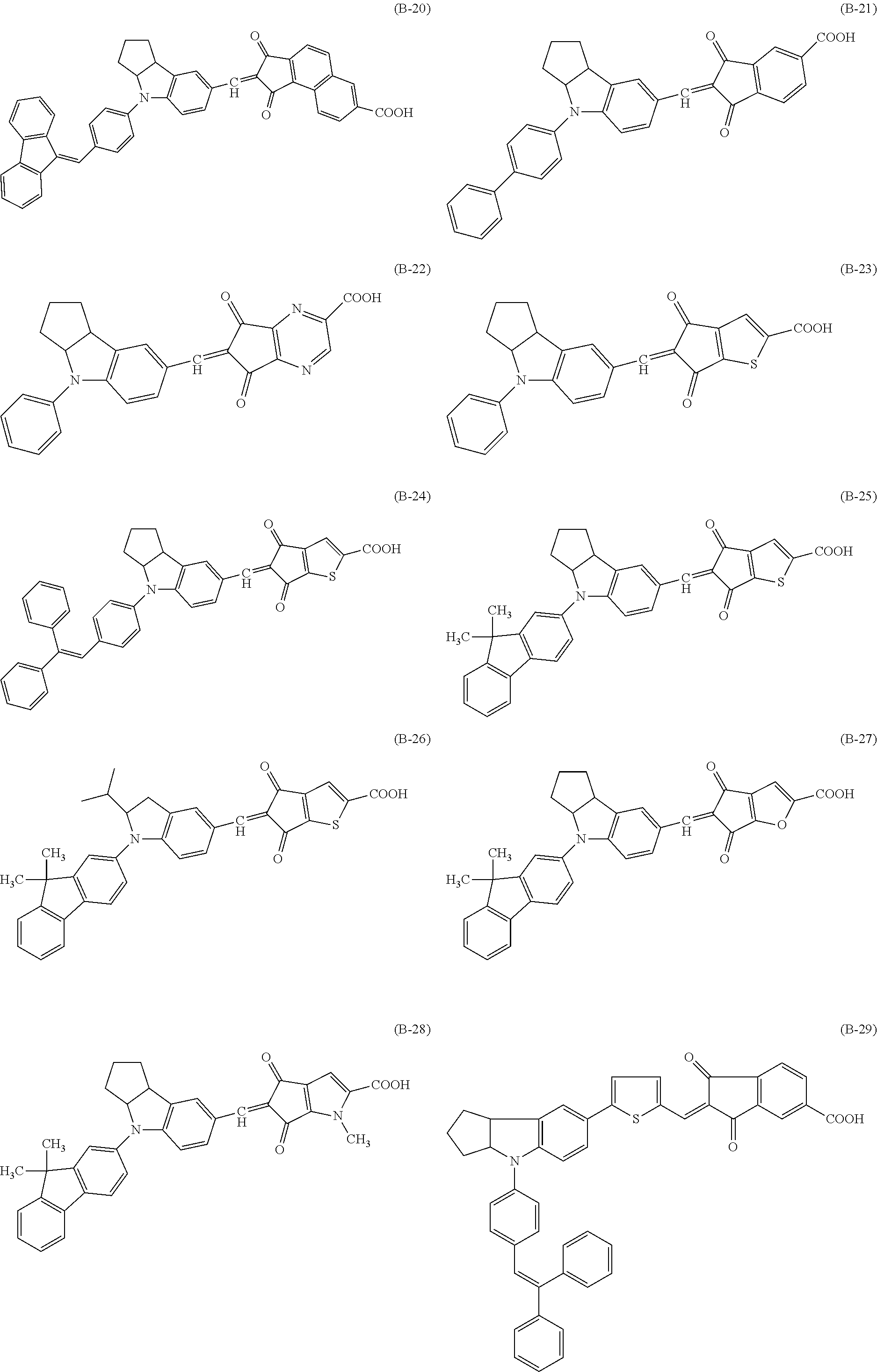

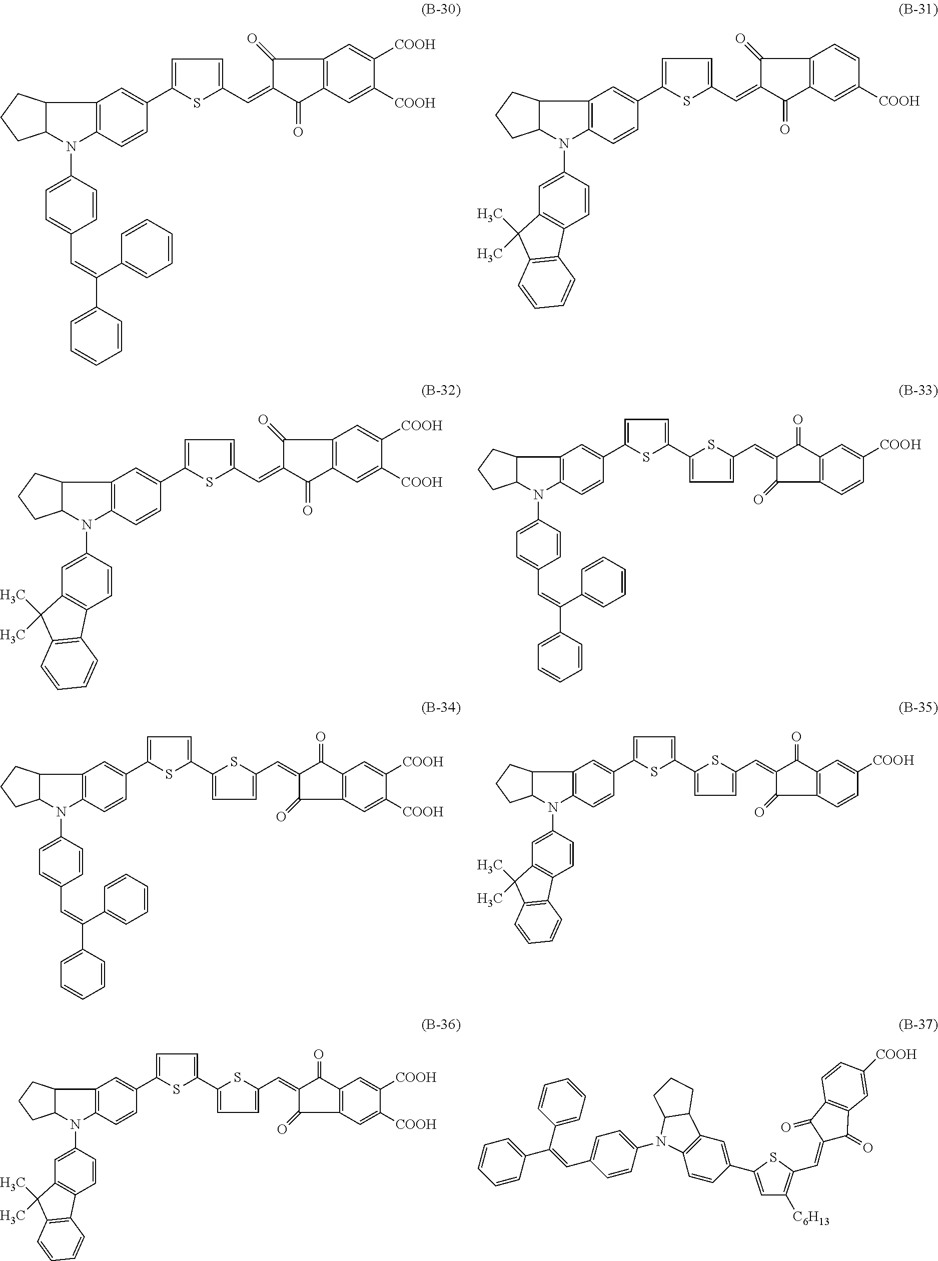

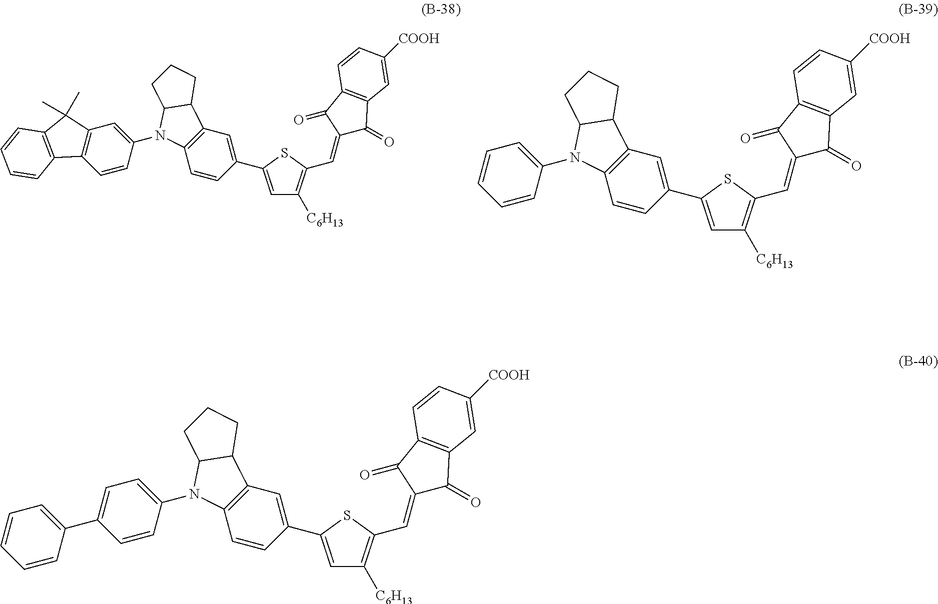

As a method for adsorbing the photosensitization compound on the electron-transporting semiconductor, for example, it is possible to use a method where an electron collecting electrode including an electron-transporting semiconductor particle is immersed in a solution or a dispersion liquid of the photosensitization compound, and a method where a solution or a dispersion liquid of the photosensitization compound is coated and adsorbed on the electron-transporting semiconductor.

Examples of the method where the electron collecting electrode including the electron-transporting semiconductor particle is immersed in the solution or the dispersion liquid of the photosensitization compound include the immersion method, the dip method, the roller method, and the air knife method.

Examples of the method where the solution or the dispersion liquid of the photosensitization compound is coated and adsorbed on the electron-transporting semiconductor include the wire bar method, the slide hopper coating method, the extrusion coating method, the curtain coating method, the spin-coating method, and the spray coating method.

Moreover, the photosensitization compound may be adsorbed in a supercritical fluid using, for example, carbon dioxide.

When the photosensitization compound is adsorbed, a condensing agent may be used in combination.

The condensing agent may be an agent exhibiting such a catalytic function that a photosensitization compound is physically or chemically bound to a surface of the electron-transporting semiconductor, or may be an agent that stoichiometrically acts and advantageously moves a chemical equilibrium.

Moreover, thiol or a hydroxyl compound may be added thereto as a condensation auxiliary.

Examples of the solvent that dissolves or disperses the photosensitization compound include water, alcohol solvents, ketone solvents, ester solvents, ether solvents, amide solvents, halogenated hydrocarbon solvents, and hydrocarbon solvents.

Examples of the alcohol solvent include methanol, ethanol, and isopropyl alcohol.

Examples of the ketone solvent include acetone, methyl ethyl ketone, and methyl isobutyl ketone.

Examples of the ester solvent include ethyl formate, ethyl acetate, and n-butyl acetate.

Examples of the ether solvent include diethyl ether, dimethoxy ethane, tetrahydrofuran, dioxolane, and dioxane.

Examples of the amide solvent include N,N-dimethylformamide, N,N-dimethylacetamide, and N-methyl-2-pyrrolidone.

Examples of the halogenated hydrocarbon solvent include dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene.

Examples of the hydrocarbon solvent include n-pentane, n-hexane, n-octane, 1,5-hexadiene, cyclohexane, methylcyclohexane, cyclohexadiene, benzene, toluene, o-xylene, m-xylene, p-xylene, ethylbenzene, and cumene.

These may be used alone or in combination.

Depending on kinds of photosensitization compounds, there is a photosensitization compound that functions more effectively when aggregation between compounds is prevented. Therefore, an aggregation dissociating agent may be used in combination.

The aggregation dissociating agent is not particularly limited and may be appropriately selected depending on a dye to be used. Examples of the aggregation dissociating agent include steroid compounds (e.g., cholic acid and chenodexycholic acid), long-chain alkyl carboxylic acid, and long-chain alkyl phosphonic acid.

An amount of the aggregation dissociating agent added is preferably 0.01 parts by mass or more but 500 parts by mass or less, more preferably 0.1 parts by mass or more but 100 parts by mass or less, relative to 1 part by mass of the photosensitization compound.

By using them, a temperature, at which the photosensitization compound, or the photosensitization compound and the aggregation dissociating agent are adsorbed, is preferably −50° C. or more but 200° C. or less.

The aforementioned adsorption may be performed under standing still or under stirring.

A stirring method is not particularly limited and may be appropriately selected depending on the intended purpose. Examples of the stirring method include a stirrer, a ball mill, a paint conditioner, a sand mill, Attritor, a disperser, and ultrasonic dispersion.

The time required for the adsorption is preferably 5 seconds or more but 1,000 hours or less, more preferably 10 seconds or more but 500 hours or less, still more preferably 1 minute or more but 150 hours or less.

The adsorption is preferably performed in the dark place.

### <<Hole-Transporting Layer>>

The hole-transporting layer includes at least an organic hole-transporting material and a lithium salt, and further includes other components if necessary.

The hole-transporting layer is preferably a solid.

The hole-transporting layer may be a single layer structure formed of a single material or may be a stacked structure formed of a plurality of compounds.

As an organic hole-transporting material used when the hole-transporting layer is a single layer structure, known organic hole-transporting compounds are used.

Specific examples thereof include oxadiazole compounds described in, for example, Japanese Examined Patent Publication No. 34-5466, triphenylmethane compounds described in, for example, Japanese Examined Patent Publication No. 45-555, pyrazoline compounds described in, for example, Japanese Examined Patent Publication No. 52-4188, hydrazone compounds described in, for example, Japanese Examined Patent Publication No. 55-42380, oxadiazole compounds described in, for example, Japanese Unexamined Patent Application Publication No. 56-123544, tetraarylbenzidine compounds described in, for example, Japanese Unexamined Patent Application Publication No. 54-58445, and stilbene compounds described in, for example, Japanese Unexamined Patent Application Publication No. 58-65440 or Japanese Unexamined Patent Application Publication No. 60-98437.

Among them, spiro compounds are particularly preferable. Examples of the spiro compound include compounds including the following General Formula (4).

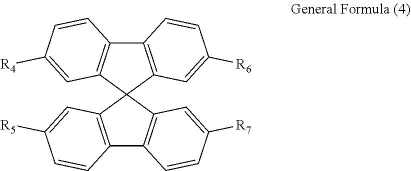

In the General Formula (4), R₄ to R₇ each independently represent a substituted amino group such as a dimethylamino group, a diphenylamino group, or a naphthyl-4-tolylamino group.

The spiro compound is not particularly limited and may be appropriately selected depending on the intended purpose. Examples of the spiro compound include, but are not limited to, the following exemplified compounds D-1 to D-20. These may be used alone or in combination.

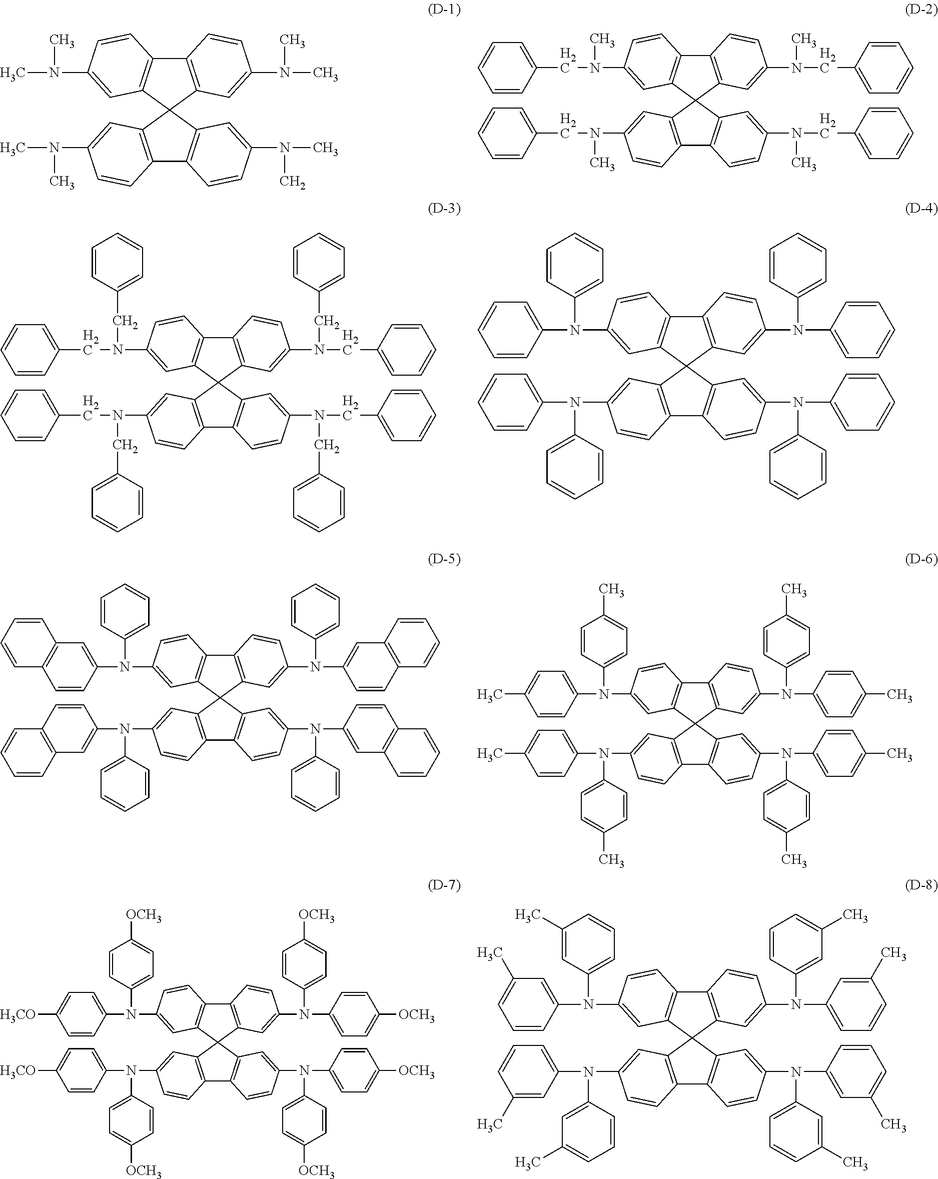

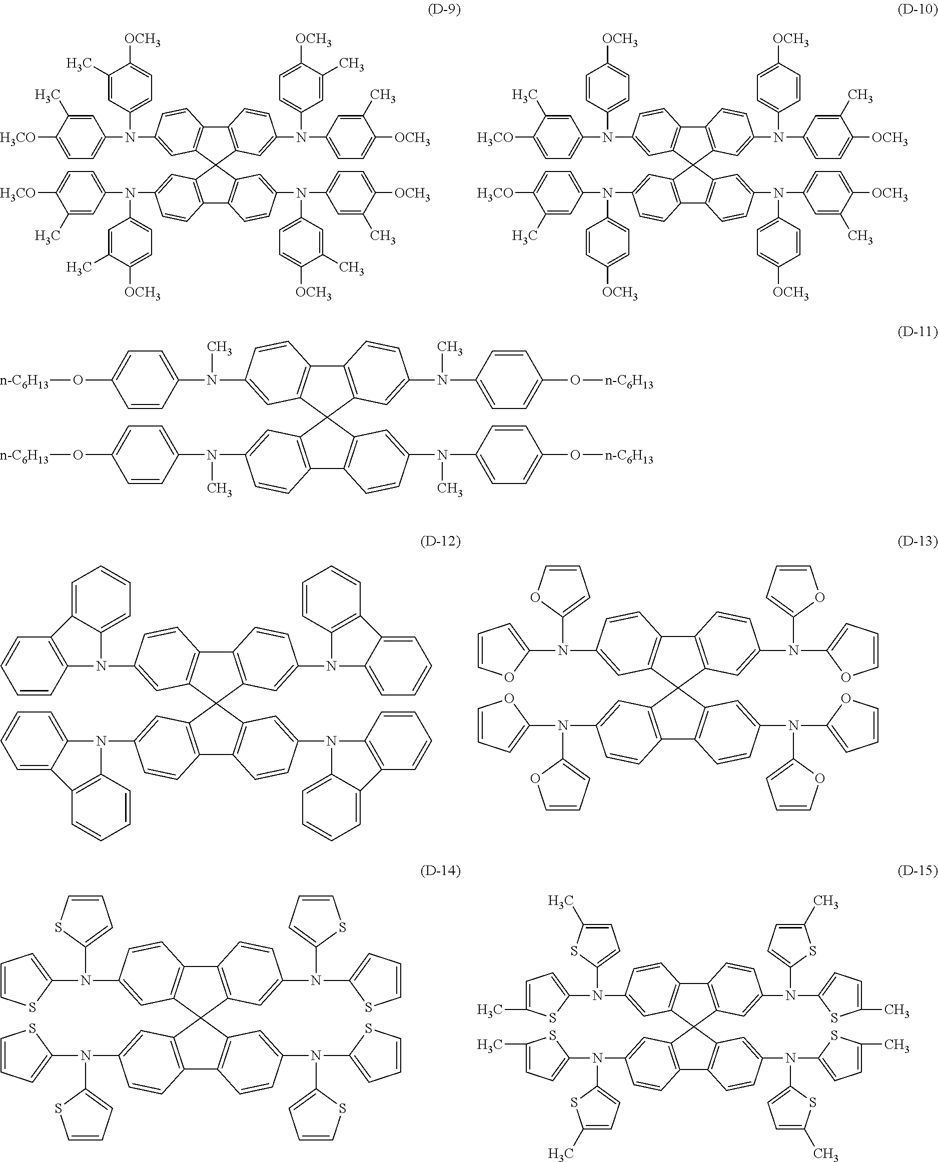

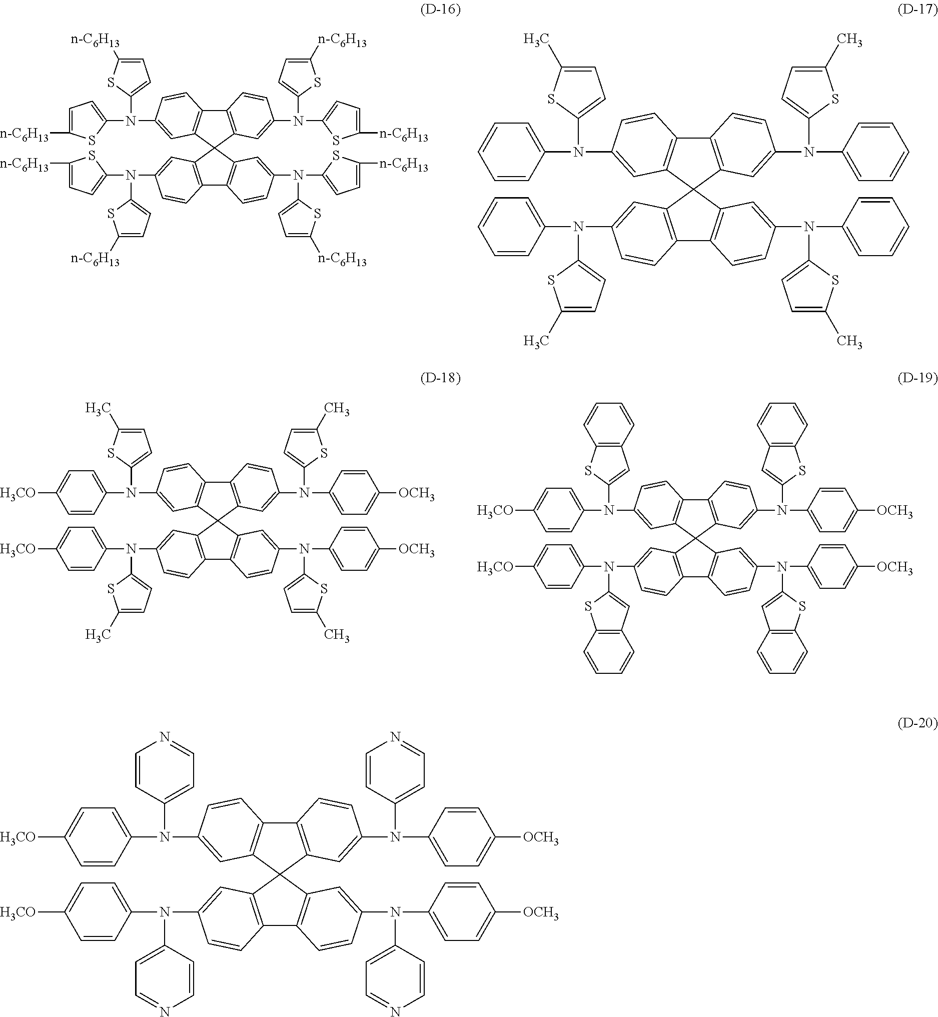

Because these spiro compounds have high hole mobility and two benzidine skeleton molecules are spirally bound, a nearly spherical electron cloud is formed and hopping conductivity between molecules is excellent. Therefore, the spiro compounds exhibit excellent photoelectric conversion properties. Moreover, the spiro compounds are dissolved in various organic solvents because of high solubility. Because the spiro compounds are amorphous (amorphous substances that do not have a crystal structure), the spiro compounds tend to be densely filled in a porous electron-transporting layer. Because the spiro compounds do not absorb light of 450 nm or longer, light absorption of the photosensitization compound can be effectively performed, which is particularly preferable for a solid dye-sensitized solar cell.

An amount of the organic hole-transporting material in the hole-transporting layer is not particularly limited and may be appropriately selected depending on the intended purpose.

The lithium salt is not particularly limited and may be appropriately selected depending on the intended purpose so long as it is a salt including lithium. Examples of the lithium salt include lithium hexafluorophosphate (LiPF₆), lithium perchlorate (LiClO₄), lithium chloride (LiCl), lithium tetrafluoroborate (LiBF₄), lithium hexafluoride arsenic (LiAsF₆), lithium trifluoromethanesulfonate (LiCF₃SO₃), lithium bis(trifluoromethanesulfonyl)imide [LiN(CF₃SO₂)₂], lithium (fluorosulfonyl)(trifluoromethanesulfonyl)imide [LiNSO₂)(CF₃SO₂)₂], lithium bis(pentafluoroethanesulfonyl)imide [LiN(C₂F₅SO₂)₂], lithium bis(fluorosulfonyl)imide [LiN(FSO₂)₂], lithium diisopropylimide, lithium (fluorosulfonyl)(methylsulfonyl)imide, lithium (fluorosulfonyl)(pentafluoroethylsulfonyl)imide, and lithium (fluorosulfonyl)(ethylsulfonyl)imide. These may be used alone or in combination.

Among them, lithium bis(trifluoromethanesulfonyl)imide, lithium bis(fluorosulfonyl)imide, and lithium (fluorosulfonyl)(trifluoromethanesulfonyl)imide are more preferable.

An amount of the lithium salt in the hole-transporting layer is not particularly limited and may be appropriately selected depending on the intended purpose. The amount of the lithium salt in the hole-transporting layer is preferably 5% by mole or more but 50% by mole or less, more preferably 20% by mole or more but 35% by mole or less, relative to the hole-transporting material.

The hole-transporting layer further includes an oxidizing agent, which is effective.

The oxidizing agent has a function of oxidizing a hole-transporting material to generate cation radicals. The hole-transporting material is deprived of electrons (holes are supplied) by the oxidizing agent and then becomes an oxidant, to improve a hole-transporting property. This is preferable in terms of improvement of the output and the persistence of its effect.

The oxidizing agent is not particularly limited and may be appropriately selected depending on the intended purpose so long as it has a function of oxidizing the hole-transporting material. Examples thereof include tris(4-bromophenyl)aminium hexachloroantimonate, silver hexafluoroantimonate, nitrosonium tetrafluoroborate, silver nitrate, metal complexes, and hypervalent iodine compounds. These may be used alone or in combination. Among them, metal complexes are more preferable. Use of the metal complex as the oxidizing agent is advantageous because it has high solubility and remaining products do not easily remain.

Examples of the metal complex include a complex including, for example, a metal cation, a ligand, and an anion.

Examples of the metal cation include cations of, for example, chromium, manganese, iron, cobalt, nickel, copper, molybdenum, ruthenium, rhodium, palladium, silver, tungsten, rhenium, osmium, iridium, gold, and platinum. Among them, cations of iron, cobalt, nickel, and copper are preferable, and a cation of cobalt is more preferable. That is, the metal complex is more preferably a cobalt complex. The cobalt complex is preferably a trivalent cobalt complex.

The ligand preferably includes a 5-membered heterocycle and/or a 6-membered heterocycle including at least one nitrogen, and may include a substituent. Specific examples thereof include, but are not limited to, the following compounds.

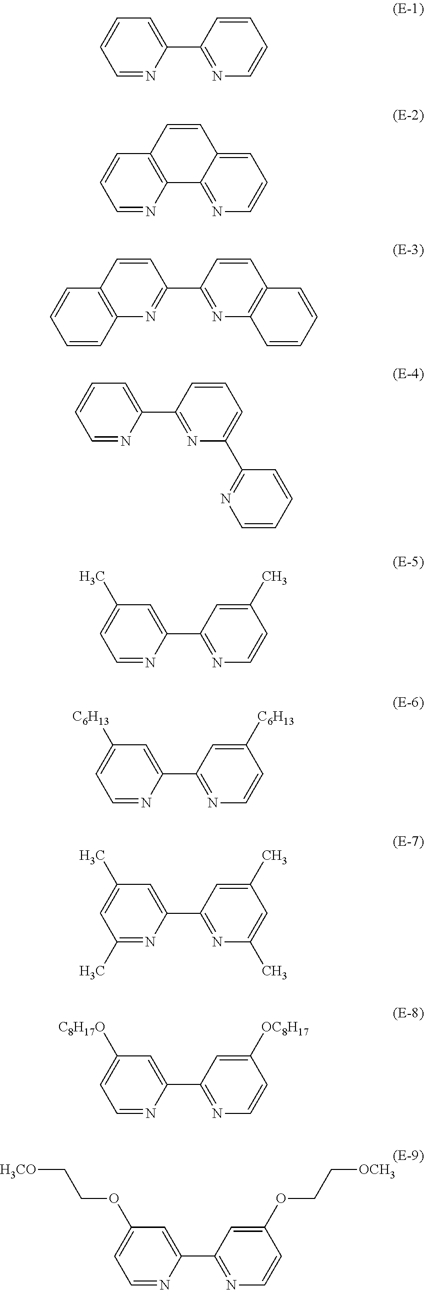

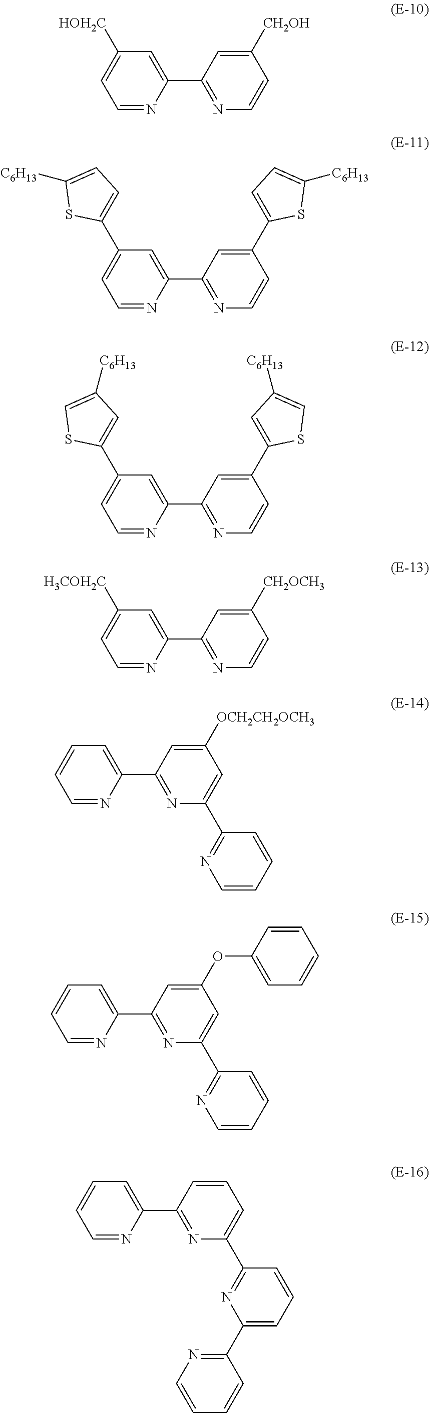

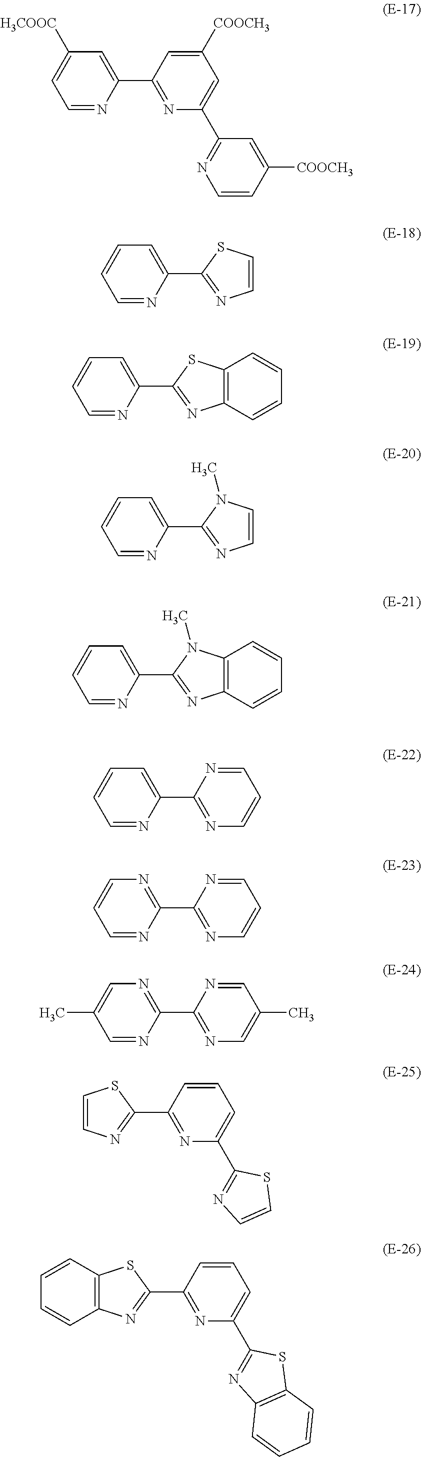

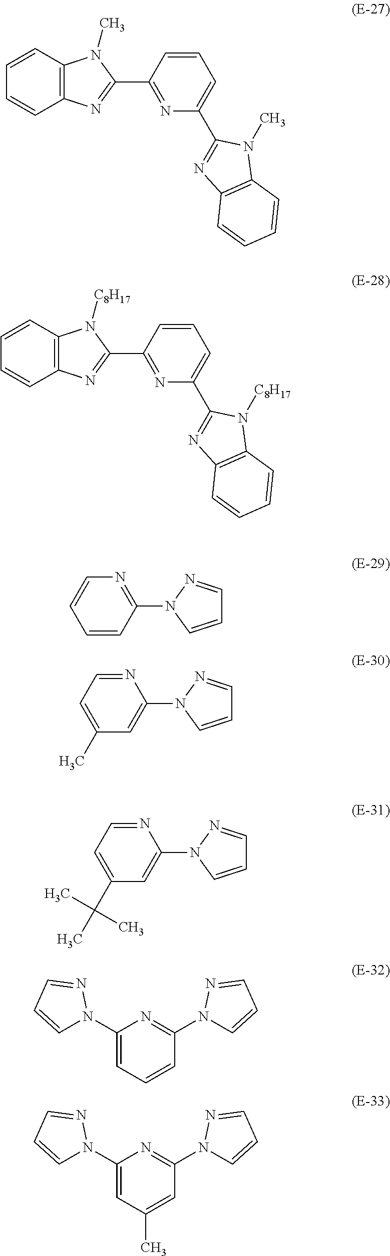

Examples of the anion include a hydride ion (H⁻), a fluoride ion (F⁻), a chloride ion (Cl⁻), a bromide ion (Br⁻), an iodide ion (I⁻), a hydroxide ion (OH⁻), a cyanide ion (CN⁻), a nitric acid ion (NO₃), a nitrous acid ion (NO₂⁻), a hypochlorous acid ion (ClO⁻), a chlorous acid ion (ClO₂⁻), a chloric acid ion (ClO₃⁻), a perchloric acid ion (ClO₄⁻), a permanganic acid ion (MnO₄⁻), an acetic acid ion (CH₃COO⁻), a hydrogen carbonate ion (HCO₃⁻), a dihydrogen phosphate ion (H₂PO₄⁻), a hydrogen sulfate ion (HSO₄⁻), a hydrogen sulfide ion (HS⁻), a thiocyanic acid ion (SCN⁻), a tetrafluoroboric acid ion (BF₄⁻), a hexafluorophosphate ion (PF₆⁻), a tetracyanoborate ion (B(CN)₄⁻), a dicyanoamine ion (N(CN)₂⁻), a p-toluenesulfonic acid ion (TsO⁻), a trifluoromethyl sulfonate ion (CF₃SO₂⁻), a bis(trifluoromethylsulfonyl)amine ion (N(SO₂CF₃)₂⁻), a tetrahydroxoaluminate ion ([Al(OH)₄]⁻ or [Al(OH)₄(H₂O)₂]⁻), a dicyanoargentate(I) ion ([Ag(CN)₂]⁻), a tetrahydroxochromate(III) ion ([Cr(OH)₄]⁻), a tetrachloroaurate(III) ion ([AuCl₄]⁻), an oxide ion (O²⁻), a sulfide ion (S²⁻), a peroxide ion (O₂²⁻), a sulfuric acid ion (SO₄²⁻), a sulfurous acid ion (SO₃²⁻), a thiosulfuric acid (S₂O₃²⁻), a carbonic acid ion (CO₃²⁻), a chromic acid ion (CrO₄²⁻), a dichromic acid ion (Cr₂O₇²⁻), a monohydrogen phosphate ion (HPO₄²⁻), a tetrahydroxozincate(II) ion ([Zn(OH)₄]²⁻), a tetracyanozincate(II) ion ([Zn(CN)₄]²⁻), a tetrachlorocuprate(II) ion ([CuCl₄]²⁻), a phosphoric acid ion (PO₄³⁻), a hexacyanoferrate(III) ion ([Fe(CN)₆]³⁻), a bis(thiosulfate)argentate(I) ion ([Ag(S₂O₃)₂]³⁻), and a hexacyanoferrate(II) ion ([Fe(CN)₁]⁴⁻). These may be used alone or in combination. Among them, a tetrafluoroboric acid ion, a hexafluorophosphate ion, a tetracyanoborate ion, a bis(trifluoromethylsulfonyl)amine ion, and a perchloric acid ion are preferable.

Among these metal complexes, trivalent cobalt complexes represented by the following General Formulas (5) and (6) are particularly preferable. When the metal complex is a trivalent cobalt complex, the function as the oxidizing agent is excellent, which is advantageous.

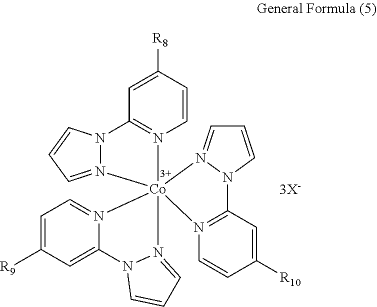

In the General Formula (5), R₈ to R₁₀ each independently represent a hydrogen atom, a methyl group, an ethyl group, a propyl group, a tert-butyl group, or a trifluoromethyl group. X⁻ represents one selected from the group consisting of the above monovalent anions.

Specific examples of the cobalt complex represented by the General Formula (5) are described below. However, the present disclosure is not limited thereto. These may be used alone or in combination.

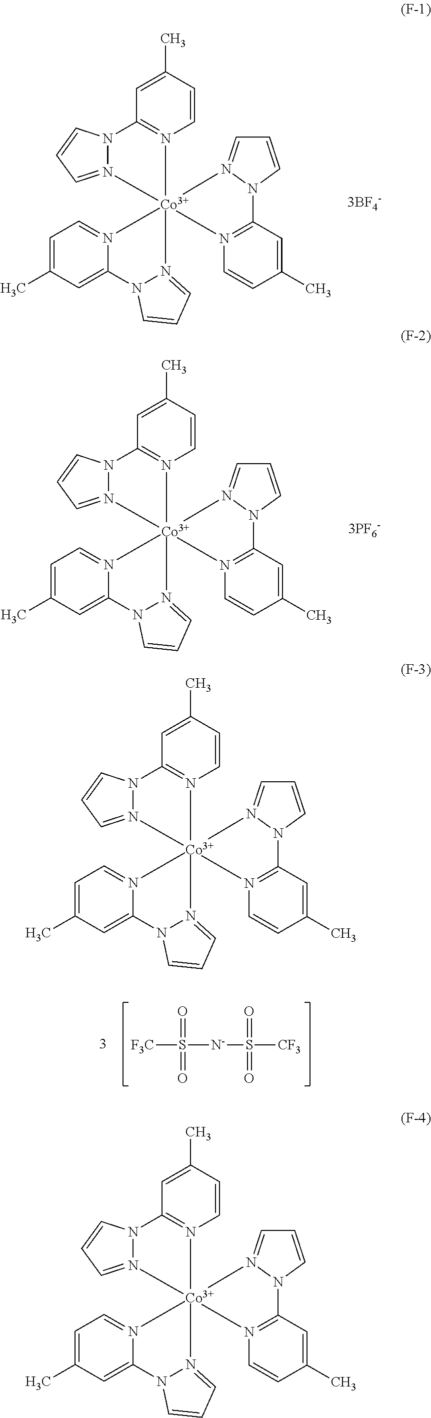

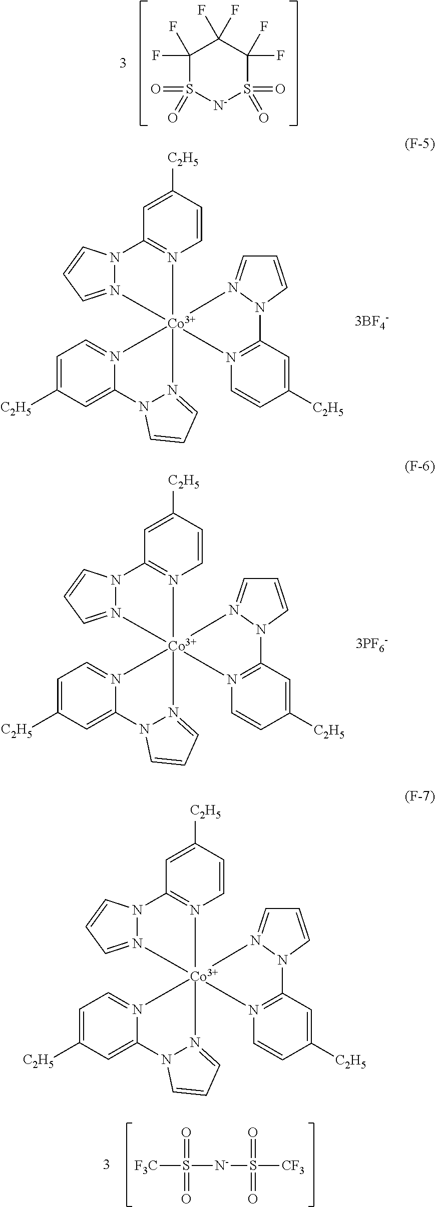

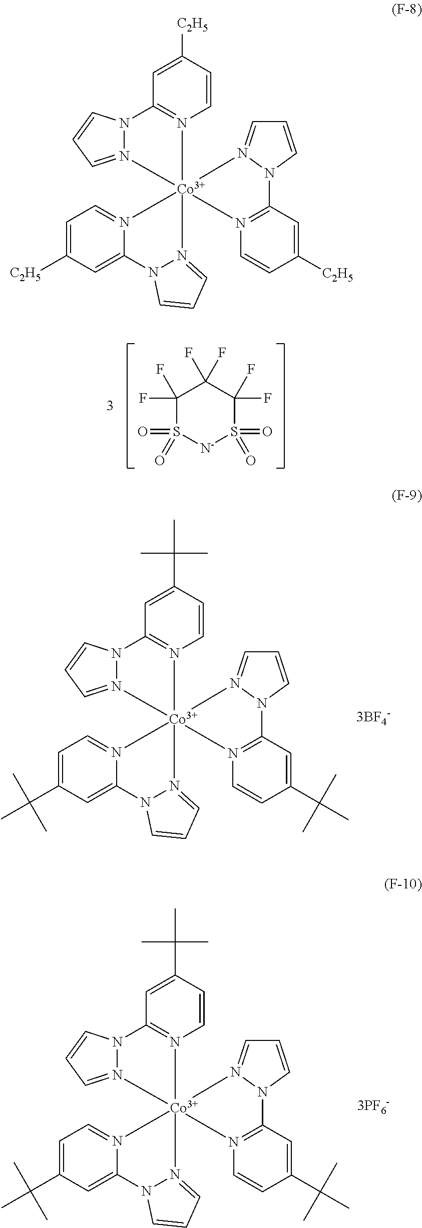

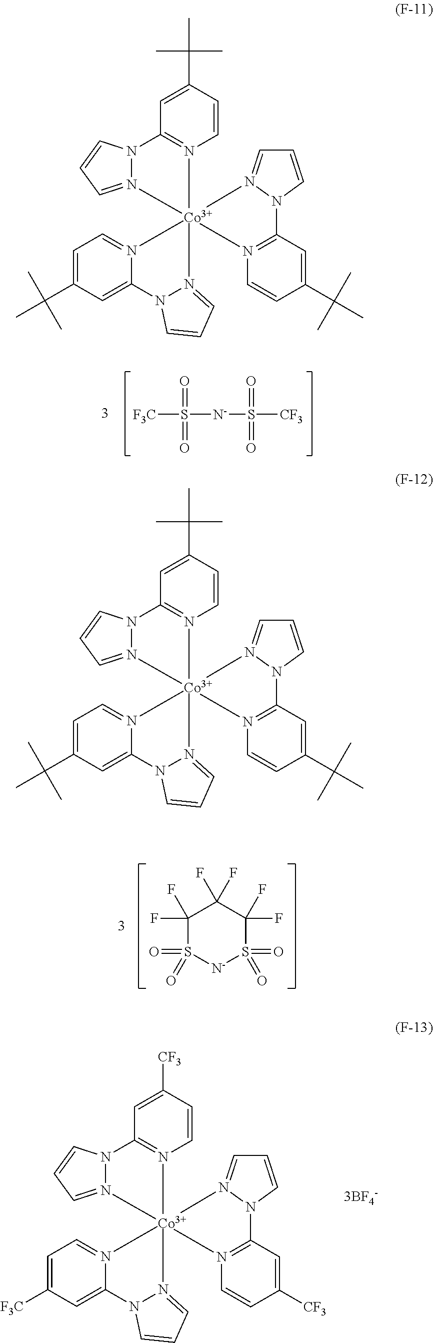

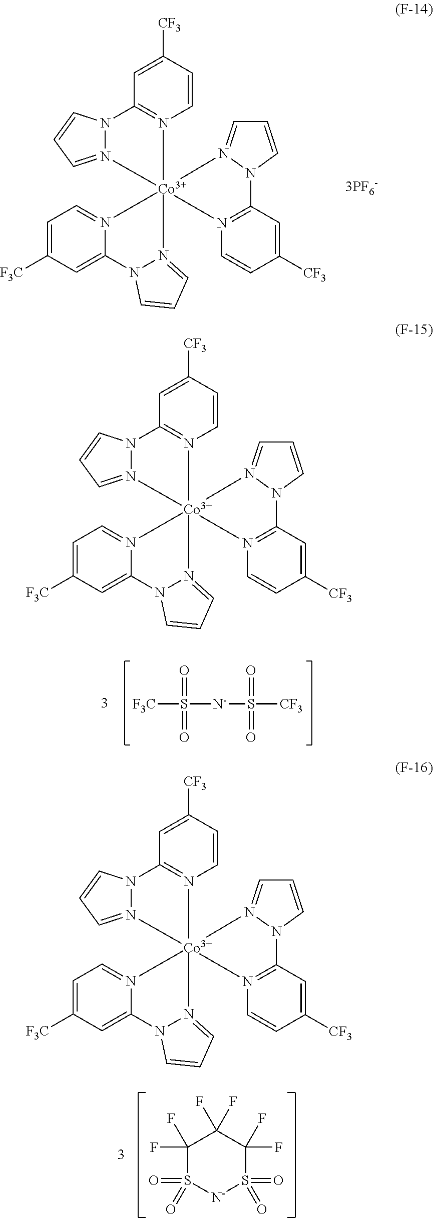

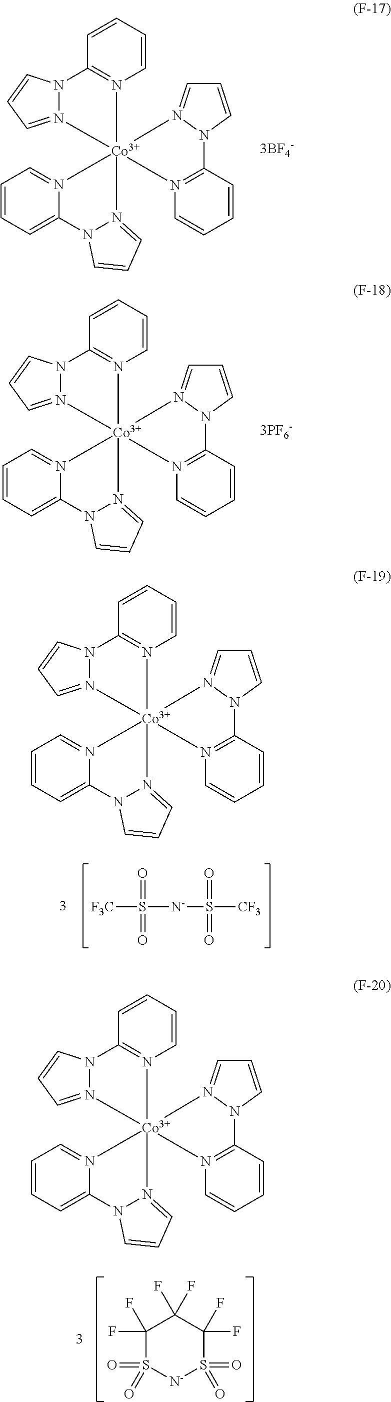

As the metal complex, a trivalent cobalt complex represented by the following General Formula (6) is also effectively used.

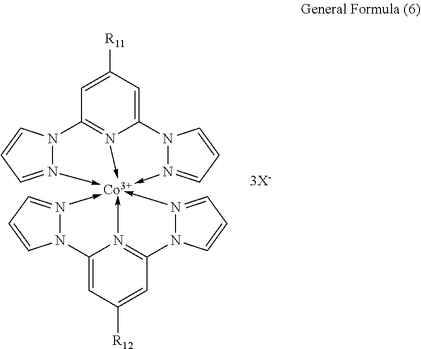

In the General Formula (6), R₁₁ and R₁₂ each independently represent a hydrogen atom, a methyl group, an ethyl group, a propyl group, a tert-butyl group, or a trifluoromethyl group. X⁻ represents one selected from the group consisting of the above monovalent anions.

Specific examples of the cobalt complex represented by the General Formula (6) are described below. However, the present disclosure is not limited thereto. These may be used alone or in combination.

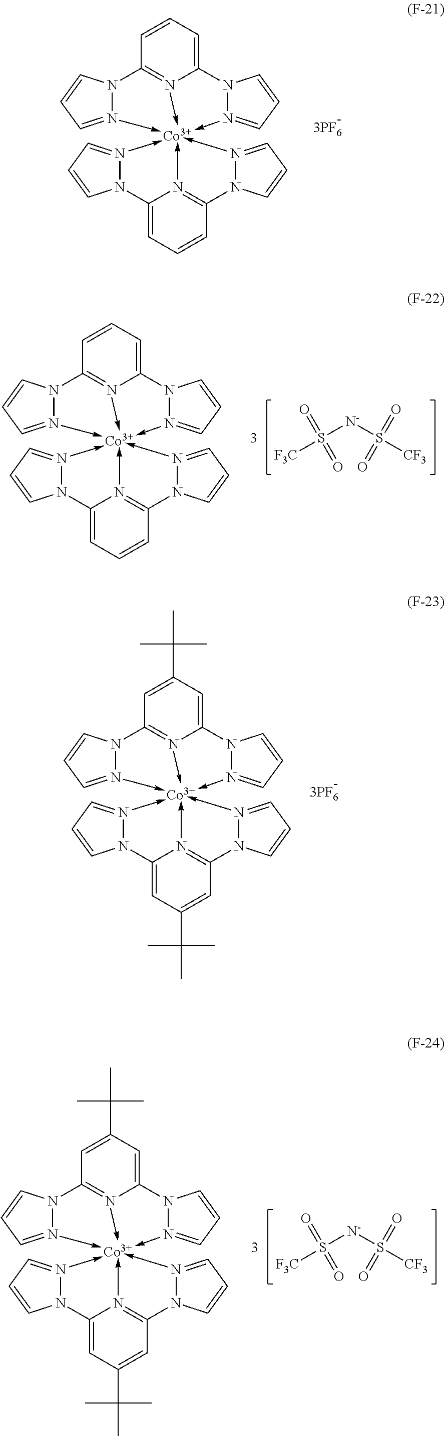

As the oxidizing agent, a hypervalent iodine compound is also preferably used. The hypervalent iodine compound is a compound that includes 8 or more electrons in the valence shell and includes a hypervalent iodine atom. Among them, particularly, when a periodinane compound represented by the following General Formula (7) and a diaryliodonium salt represented by the following General Formula (8) are used as the oxidizing agent in the hole-transporting layer, a high output can be obtained because of high solubility, low crystallinity, and low acidity. When acidity of the hole-transporting layer is high, the open circuit voltage becomes low. When the amount of a basic material added is large, it is possible to make the open circuit voltage high. However, because a concentration of the hole-transporting material is decreased, series resistance is increased to thereby decrease the output under light of a high illuminance.

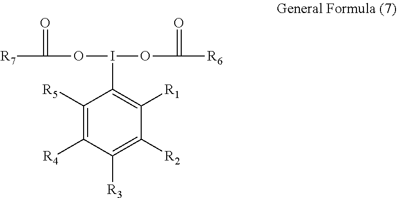

In the General Formula (7), R₁ to R₅ each independently represent a hydrogen atom or a methyl group. R₆ and R₇ each independently represent a methyl group or a trifluoromethyl group.

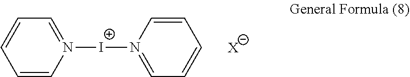

In the General Formula (8), X represents BF₄, PF₄, the following Structural Formula (4), or the following Structural Formula (5).

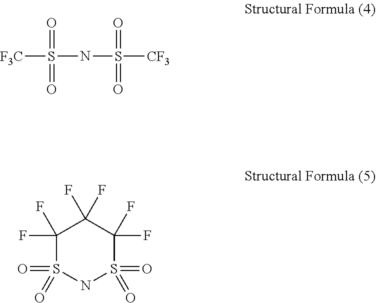

Specific examples of the periodinane compound represented by the General Formula (7) and the diaryliodonium salt represented by the General Formula (8) include, but are not limited to, the following (G-1) to (G-10).

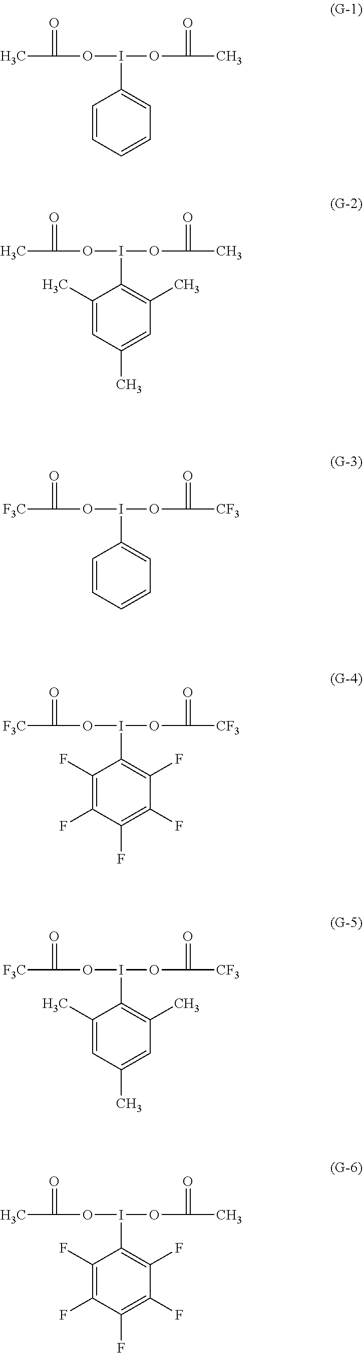

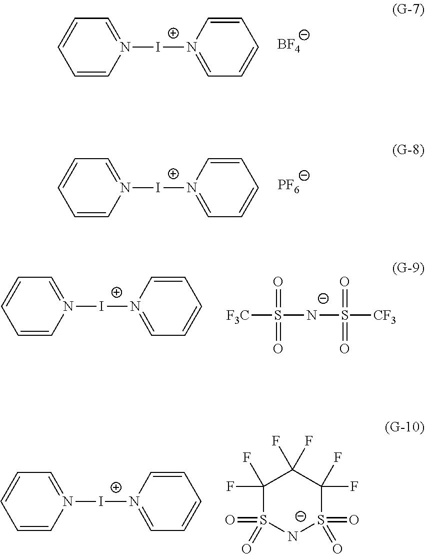

In addition, hypervalent iodine compounds expressed by the following Structural Formulas are also effective.

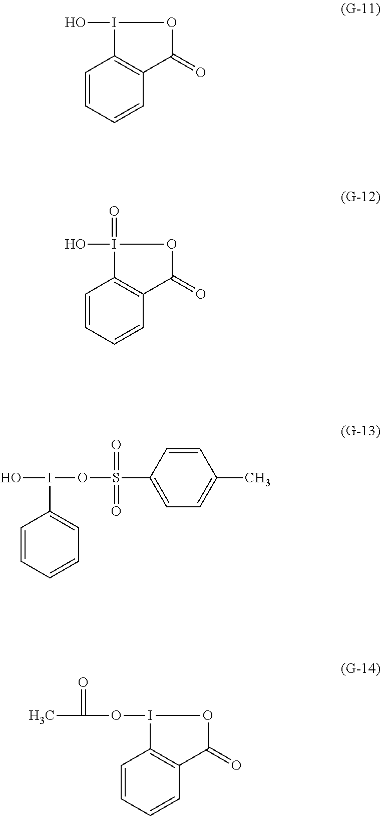

An amount of the oxidizing agent is preferably 5 mol % or more but mol % or less, more preferably 10 mol % or more but 20 mol % or less, relative to the hole-transporting material. By addition of the oxidizing agent, it is not necessary to oxidize all hole-transporting material, and it is effective so long as the hole-transporting material is partially oxidized.

The oxidizing agent may be used alone or in combination. When two or more oxidizing agents are used in combination, the hole-transporting layer is not easily crystallized and may obtain a high thermal resistance in some cases.

Preferably, the hole-transporting layer further includes a compound having a pyridine ring structure.

The pyridine ring is expressed by the following Structural Formula (6), and the compound having a pyridine ring structure is a compound including at least one pyridine ring.

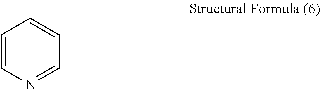

When the hole-transporting layer includes the compound having a pyridine ring structure, open circuit voltage is increased. As a result, an effect of increasing the output can be obtained.

Among these compounds having a pyridine ring structure, compounds represented by the following General Formula (9) and General Formula (10) are more preferable.

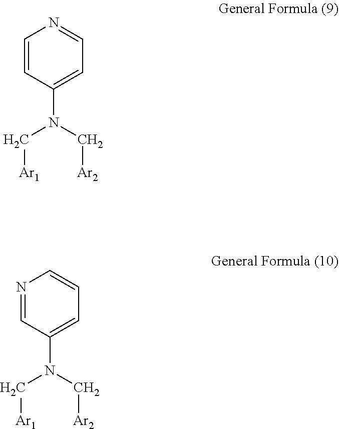

In the General Formula (9) and the General Formula (10), Ar₁ and Ar₂ represent an aryl group that may have a substituent, the Ar₁ and the Ar₂ may be identical or different, and may be joined with each other.

Specific examples of the compound having a pyridine ring include, but are not limited to, the following exemplified compounds C-1 to C-16. These may be used alone or in combination.

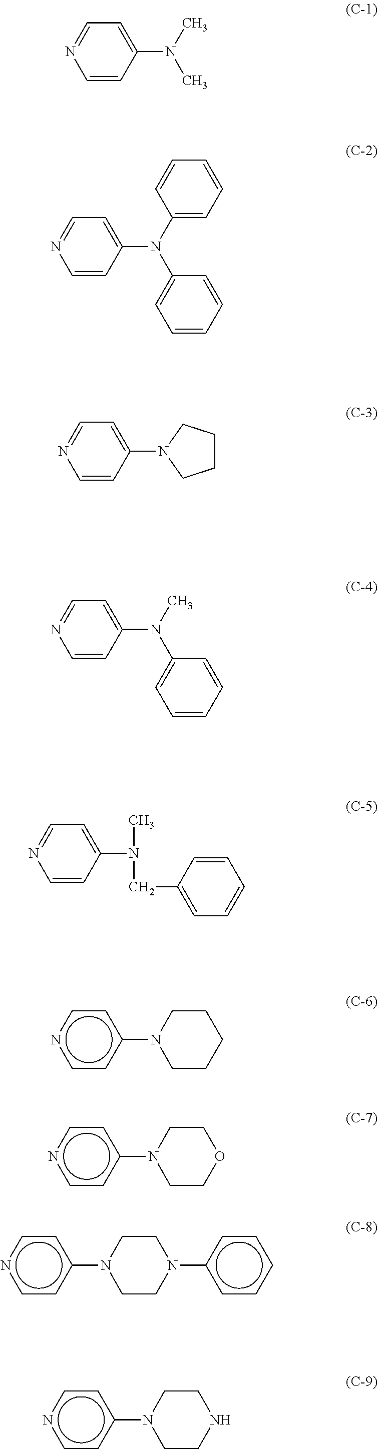

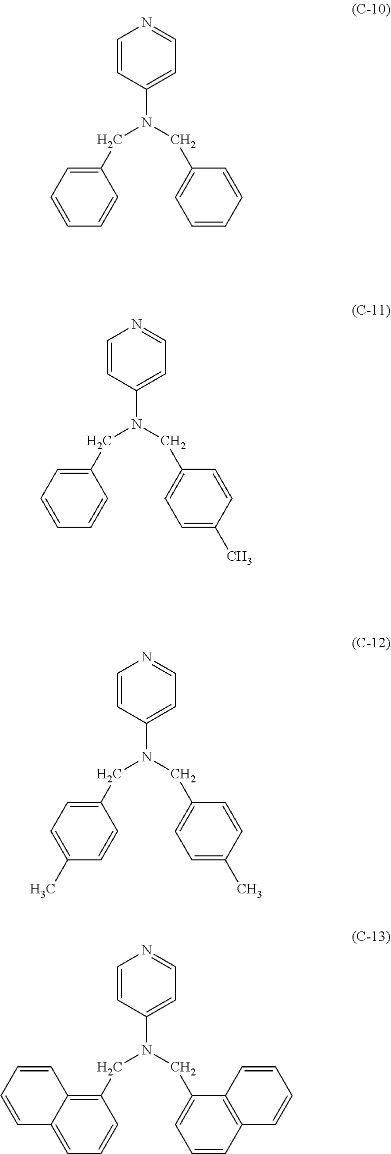 [SMILES: c1ccc(CN(Cc2ccccc2)c2ccncc2)cc1 ; Cc1ccc(CN(Cc2ccccc2)c2ccncc2)cc1 ; Cc1ccc(CN(Cc2ccc(C)cc2)c2ccncc2)cc1 ; c1ccc2c(CN(Cc3cccc4ccccc34)c3ccncc3)cccc2c1]

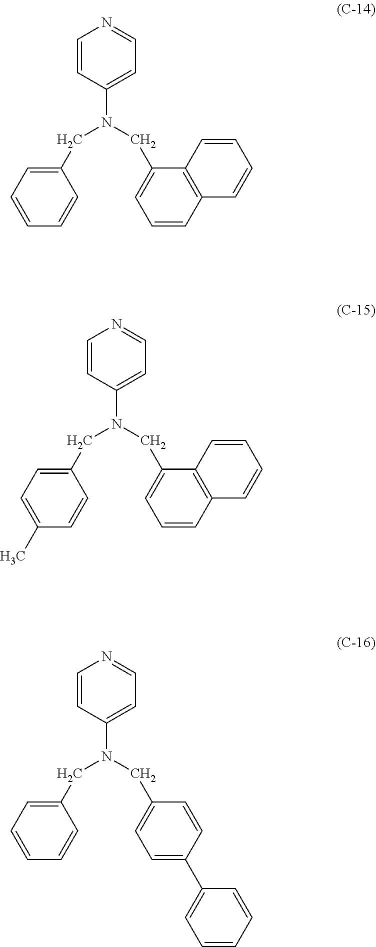 [SMILES: c1ccc(CN(Cc2cccc3ccccc23)c2ccncc2)cc1 ; Cc1ccc(CN(Cc2cccc3ccccc23)c2ccncc2)cc1 ; c1ccc(CN(Cc2ccc(-c3ccccc3)cc2)c2ccncc2)cc1]

Inclusion of the compound having a pyridine ring structure in the hole-transporting layer can enhance not only the output of the photoelectric conversion element but also the durability or the stability, and is particularly effective in improving the stability or the durability against light of a low illuminance.

An amount of the compound having a pyridine ring is preferably mol % or more but 65 mol % or less, more preferably 35 mol % or more but 50 mol % or less, relative to the hole-transporting material. When the amount of the compound having a pyridine ring falls within the preferable range, a high open circuit voltage can be maintained, and a high output can be obtained. In addition, even when the photoelectric conversion element is used under various environments for a long period of time, high stability and durability can be obtained.

Various additives may be added to the organic hole-transporting material.

Examples of the additive include iodine, metal iodides, quaternary ammonium salts, metal bromides, metal chlorides, metal acetates, metal sulfates, metal complexes, sulfur compounds, ionic liquids described in Inorg. Chem. 35 (1996) 1168, and basic compounds.

Examples of the metal iodide include sodium iodide, potassium iodide, cesium iodide, calcium iodide, copper iodide, iron iodide, and silver iodide.

Examples of the quaternary ammonium salt include tetraalkylammonium iodide and pyridinium iodide.

Examples of the metal bromide include sodium bromide, potassium bromide, cesium bromide, and calcium bromide.

Examples of the metal chloride include: bromide salts of quaternary ammonium compounds such as tetraalkylammonium bromide and pyridinium bromide; copper chloride; and silver chloride.

Examples of the metal acetate include copper acetate, silver acetate, and palladium acetate.

Examples of the metal sulfate include copper sulfate and zinc sulfate.

Examples of the metal complex include a ferrocyanate salt-ferricyanate salt and a ferrocene-ferricinium ion.

Examples of the sulfur compound include sodium polysulfide and alkylthiol-alkyl disulfide.

Examples of the ionic liquid described in Inorg. Chem. 35 (1996) 1168 include viologen dye, hydroquinone, 1,2-dimethyl-3-n-propylimidazolium iodide, 1-methyl-3-n-hexylimidazolium iodide, 1,2-dimethyl-3-ethylimidazolium trifluoromethanesulfonate, 1-methyl-3-butylimidazolium nonafluorobutyl sulfonate, and 1-methyl-3-ethylimidazolium bis(trifluoromethyl)sulfonyl imide.

When the hole-transporting layer is a staked structure, a polymeric material is preferably used on the hole-transporting layer near the second electrode. Use of the polymeric material excellent in a film forming property can make the surface of a porous electron-transporting layer smoother, to improve photoelectric conversion characteristics.

Because the polymeric material does not easily permeate through the inside of the porous electron-transporting layer, the polymeric material is excellent in coating the surface of the porous electron-transporting layer and can achieve an effect of preventing short circuit when an electrode is provided. As a result, higher performances can be obtained.

The polymeric material, which is used when the hole-transporting layer has a stacked structure and is disposed at a position near the second electrode, is not particularly limited. More preferable examples of the polymeric material include known hole-transporting polymeric materials.

Examples of the hole-transporting polymeric material include polythiophene compounds, polyphenylene vinylene compounds, polyfluorene compounds, polyphenylene compounds, polyarylamine compounds, and polythiadiazole compounds.

Examples of the polythiophene compound include poly(3-n-hexylthiophene), poly(3-n-octyloxythiophene), poly(9,9′-dioctyl-fluorene-co-bithiophene), poly(3,3′″-didodecyl-quarter thiophene), poly(3,6-dioctylthieno[3,2-b]thiophene), poly(2,5-bis(3-decylthiophen-2-yl)thieno[3,2-b]thiophene), poly(3,4-didecylthiophene-co-thieno[3,2-b]thiophene), poly(3,6-dioctylthieno[3,2-b]thiophene-co-thieno[3,2-b]thiophene), poly(3,6-dioctylthieno[3,2-b]thiophene-co-thiophene), and poly(3,6-dioctylthieno[3,2-b]thiophene-co-bithiophene).

Examples of the polyphenylene vinylene compound include poly[2-methoxy-5-(2-ethylhexyloxy)-1,4-phenylenevinylene], poly[2-methoxy-5-(3,7-dimethyloctyloxy)-1,4-phenylenevinylene], and poly[(2-methoxy-5-(2-ethylhexyloxy)-1,4-phenylenevinylene)-co-(4,4′-biphenylene-vinylene)].

Examples of the polyfluorene compound include poly(9,9′-didodecylfluorenyl-2,7-diyl), poly[(9,9-dioctyl-2,7-divinylenefluorene)-alt-co-(9,10-anthracene)], poly[(9,9-dioctyl-2,7-divinylenefluorene)-alt-co-(4,4′-biphenylene)], poly[(9,9-dioctyl-2,7-divinylenefluorene)-alt-co-(2-methoxy-5-(2-ethylhexyloxy)-1,4-phenylene)], and poly[(9,9-dioctyl-2,7-diyl)-co-(1,4-(2,5-dihexyloxy)benzene)].

Examples of the polyphenylene compound include poly[2,5-dioctyloxy-1,4-phenylene] and poly[2,5-di(2-ethylhexyloxy-1,4-phenylene].

Examples of the polyarylamine compound include poly[(9,9-dioctylfluorenyl-2,7-diyl)-alt-co-(N,N′-diphenyl)-N,N′-di(p-hexylphenyl)-1,4-diaminobenzene], poly[(9,9-dioctylfluorenyl-2,7-diyl)-alt-co-(N,N′-bis(4-octyloxyphenyl)benzi dine-N,N′-(1,4-diphenylene)], poly[(N,N′-bis(4-octyloxyphenyl)benzidine-N,N′-(1,4-diphenylene)], poly[(N,N′-bis(4-(2-ethylhexyloxy)phenyl)benzidine-N,N′-(1,4-diphenylene)], poly[phenylimino-1,4-phenylenevinylene-2,5-dioctyloxy-1,4-phenylenevinylene-1,4-phenylene], poly[p-tolylimino-1,4-phenylenevinylene-2,5-di(2-ethylhexyloxy)-1,4-phenylenevinylene-1,4-phenylene], and poly[4-(2-ethylhexyloxy)phenylimino-1,4-biphenylene].

Examples of the polythiadiazole compound include poly[(9,9-dioctylfluorenyl-2,7-diyl)-alt-co-(1,4-benzo(2,1′,3)thiadiazole] and poly(3,4-didecylthiophene-co-(1,4-benzo(2,1′,3)thiadiazole).

Among them, polythiophene compounds and polyarylamine compounds are particularly preferable in terms of carrier mobility and ionization potential.

The hole-transporting layer can be directly formed on the electron-transporting layer including the photosensitization compound.

A method for producing the hole-transporting layer is not particularly limited and may be appropriately selected depending on the intended purpose. Examples of the method include a method for forming a thin film under vacuum such as vacuum deposition and a wet film formation method. Among them, particularly, the wet film formation method is preferable, a method for performing coating on the electron-transporting layer is preferable in terms of production cost.

When the wet film formation method is used, the coating method is not particularly limited and can be performed according to known methods. Examples of the coating method include the dip method, the spray method, the wire bar method, the spin-coating method, the roller coating method, the blade coating method, and the gravure coating method. Examples of the wet printing method include various methods such as relief printing, offset printing, gravure printing, intaglio printing, rubber plate printing, and screen printing.

The film may be formed in a supercritical fluid or a subcritical fluid having lower temperature and pressure than a critical point.

The supercritical fluid is not particularly limited and may be appropriately selected depending on the intended purpose, so long as it exists as a non-condensable high-density fluid in a temperature and pressure region exceeding the limit (critical point) at which gas and liquid can coexist, does not condense even when compressed, and is fluid in a state of being equal to or more than the critical temperature and the critical pressure. The supercritical fluid is preferably a supercritical fluid having a low critical temperature.

Examples of the supercritical fluid include carbon monoxide, carbon dioxide, ammonia, nitrogen, water, alcohol solvents, hydrocarbon solvents, halogen solvents, and ether solvents.

Examples of the alcohol solvent include methanol, ethanol, and n-butanol.

Examples of the hydrocarbon solvent include ethane, propane, 2,3-dimethylbutane, benzene, and toluene.

Examples of the halogen solvent include methylene chloride and chlorotrifluoromethane.

Examples of the ether solvent include dimethyl ether.

These may be used alone or in combination.

Among them, carbon dioxide having a critical pressure of 7.3 MPa and a critical temperature of 31° C. is particularly preferable because it can easily generate a supercritical state, has incombustibility, and is easily handled.

The subcritical fluid is not particularly limited and may be appropriately selected depending on the intended purpose so long as it exists as high-pressure liquid in a temperature and pressure region near the critical point.

The aforementioned compounds exemplified as the supercritical fluid can be suitably used as the subcritical fluid.

A critical temperature and a critical pressure of the supercritical fluid are not particularly limited and may be appropriately selected depending on the intended purpose. The critical temperature thereof is preferably −273° C. or more but 300° C. or less, particularly preferably 0° C. or more but 200° C. or less.

In addition to the supercritical fluid and the subcritical fluid, an organic solvent or an entrainer may be used in combination. The solubility in the supercritical fluid can be more easily adjusted by addition of the organic solvent or the entrainer.

The organic solvent is not particularly limited and may be appropriately selected depending on the intended purpose. Examples thereof include ketone solvents, ester solvents, ether solvents, amide solvents, halogenated hydrocarbon solvents, and hydrocarbon solvents.

Examples of the ketone solvent include acetone, methyl ethyl ketone, and methyl isobutyl ketone.

Examples of the ester solvent include ethyl formate, ethyl acetate, and n-butyl acetate.

Examples of the ether solvent include diisopropyl ether, dimethoxy ethane, tetrahydrofuran, dioxolane, and dioxane.

Examples of the amide solvent include N,N-dimethylformamide, N,N-dimethylacetamide, and N-methyl-2-pyrrolidone.

Examples of the halogenated hydrocarbon solvent include dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene.

Examples of the hydrocarbon solvent include n-pentane, n-hexane, n-octane, 1,5-hexadiene, cyclohexane, methylcyclohexane, cyclohexadiene, benzene, toluene, o-xylene, m-xylene, p-xylene, ethylbenzene, and cumene.

These may be used alone or in combination.

A press treatment may be performed after the organic hole-transporting material is provided on the electron-transporting layer containing the electron-transporting material to which the photosensitization compound has been adsorbed. It is believed that the press treatment allows the organic hole-transporting material to further adhere to the electron-transporting layer that is a porous electrode, resulting in improvement of efficiency.

The press treatment is not particularly limited and may be appropriately selected depending on the intended purpose. Examples of the press treatment include: a press molding method using a plate such as an IR tablet molding device; and a roll press method using a roller.

The pressure for the press treatment is preferably 10 kgf/cm² or more, more preferably 30 kgf/cm² or more.

The time of the press treatment is not particularly limited and may be appropriately selected depending on the intended purpose. The time thereof is preferably 1 hour or shorter. Moreover, heat may be applied at the time of the press treatment.

At the time of the press treatment, a release agent may be disposed between a pressing machine and electrodes.

Examples the release agent include fluororesins such as polyethylene tetrafluoride, polychloroethylene trifluoride, ethylene tetrafluoride-propylene hexafluoride copolymers, perfluoroalkoxy fluoride resins, polyvinylidene fluoride, ethylene-ethylene tetrafluoride copolymers, ethylene-chloroethylene trifluoride copolymers, and polyvinyl fluoride. These may be used alone or in combination.

An average thickness of the hole-transporting layer is 0.1 nm or more but 50 nm or less, more preferably 1 nm or more but 10 nm or less.

A metal oxide may be disposed between the organic hole-transporting material and the second electrode after the press treatment but before disposition of the second electrode.

Examples of the metal oxide include molybdenum oxide, tungsten oxide, vanadium oxide, and nickel oxide. These may be used alone or in combination. Among them, molybdenum oxide is preferable.

A method for disposing the metal oxide on the hole-transporting layer is not particularly limited and may be appropriately selected depending on the intended purpose. Examples of the method include a method where a thin film is formed in vacuum (e.g., sputtering and vacuum vapor deposition), and the wet film formation method.

The wet film formation method is preferably a method where a paste obtained by dispersing powder or sol of the metal oxide is prepared and is coated on the hole-transporting layer.

In the case where the wet film formation method is used, a coating method is not particularly limited and may be appropriately selected depending on the intended purpose. Examples of the coating method include the dip method, the spray method, the wire bar method, the spin-coating method, the roller coating method, the blade coating method, and the gravure coating method. Examples of the wet printing method include relief printing, offset printing, gravure printing, intaglio printing, rubber plate printing, and screen printing.

An average thickness of the metal oxide coated is preferably 0.1 nm or more but 50 nm or less, more preferably 1 nm or more but 10 nm or less.

### <Sealing Member>

The photoelectric conversion element of the present disclosure can be provided with a sealing member, which is effective.

The sealing member is not particularly limited and may be appropriately selected depending on the intended purpose, so long as at least the hole-transporting layer can be shielded from an external environment of the photoelectric conversion element.

The purpose of shielding at least the hole-transporting layer from an external environment of the photoelectric conversion element by the sealing member is to prevent entry of excessive oxygen or moisture from the outside and to prevent mechanical breakage caused by pressing force from the outside.

A method of the sealing can be roughly classified into “frame sealing” and “surface sealing”. Specifically, the frame sealing means that sealing members are provided around the photoelectric conversion layer formed of, for example, the electron-transporting layer and the hole-transporting layer of the photoelectric conversion element, and are attached to the second substrate. The surface sealing means that the sealing member is provided on the whole surface of the power generation region, and is attached to the second substrate. The frame sealing of the former can form a hollow section inside the sealed part. Therefore, an amount of moisture or an amount of oxygen inside the sealed part can appropriately be adjusted. In addition, since the second electrode is not in contact with the sealing member, an influence caused by peeled electrodes can be decreased. Meanwhile, the “surface sealing” of the latter is excellent in preventing entry of excessive oxygen or moisture from the outside. In addition, an area where the power generation region is in contact with the sealing member is large. Therefore, the sealing strength is high, and the surface sealing is particularly suitable when a flexible substrate is used as the first substrate.

Kinds of sealing member are not particularly limited and may be appropriately selected depending on the intended purpose. Examples thereof include curable resins and glass resins having a low melting temperature. The curable resin is not particularly limited and may be appropriately selected depending on the intended purpose so long as it is cured by light or heat. Among them, acrylic resins or epoxy resins are preferably used.

As a cured product of the acrylic resin, any of materials known in the art can be used, so long as the cured product is a product obtained by curing a monomer or an oligomer including an acrylic group in a molecule thereof.

As a cured product of the epoxy resin, any of materials known in the art can be used, so long as the cured product is a product obtained by curing a monomer or an oligomer including an epoxy group in a molecule thereof.

Among them, an epoxy resin having a high adhesive force with a substrate and an excellent barrier property against moisture or oxygen is more preferably used. As a result, it is possible to further enhance the durability of the photoelectric conversion element of the present disclosure that has a high output and an excellent stability.

Examples of the epoxy resin include water-dispersing epoxy resins, non-solvent epoxy resins, solid epoxy resins, thermosetting epoxy resins, curing agent-mixed epoxy resins, and ultraviolet ray-curable epoxy resins. Among them, thermosetting epoxy resins and ultraviolet ray-curable epoxy resins are preferable, ultraviolet ray-curable epoxy resins are more preferable. Note that, ultraviolet ray-curable epoxy resins may be heated.

The epoxy resin is not particularly limited and may be appropriately selected depending on the intended purpose. Examples of the epoxy resin include bisphenol A-based epoxy resins, bisphenol F-based epoxy resins, novolac-based epoxy resins, alicyclic epoxy resins, long-chain aliphatic epoxy resins, glycidyl amine-based epoxy resins, glycidyl ether-based epoxy resins, and glycidyl ester-based epoxy resins. These may be used alone or in combination.

The sealing member may include a curing agent and various additives if necessary.

Examples of the curing agent include amine-based curing agents, acid anhydride-based curing agents, polyamide-based curing agents, and other curing agents.

Examples of the amine-based curing agent include: aliphatic polyamines such as diethylenetriamine and triethylenetetramine; and aromatic polyamines such as methphenylenediamine, diaminodiphenylmethane, and diaminodiphenylsulfone.

Examples of the acid anhydride-based curing agent include phthalic anhydride, tetrahydrophthalic anhydride, hexahydrophthalic anhydride, methyltetrahydrophthalic anhydride, methylnadic anhydride, pyromellitic anhydride, HET anhydride, and dodecenylsuccinic anhydride.

Examples of other curing agents include imidazoles and polymercaptan. These may be used alone or in combination.

Examples of the additive include fillers, gap agents, polymerization initiators, drying agents (moisture absorbents), curing accelerators, coupling agents, flexibilizers, colorants, flame retardant auxiliaries, antioxidants, and organic solvents. These may be used alone or in combination. Among them, fillers, gap agents, curing accelerators, polymerization initiators, and drying agents (moisture absorbents) are preferable, and fillers and polymerization initiators are particularly preferable.

The filler is effective in preventing entry of moisture or oxygen under an external environment. In addition, the filler can obtain effects such as a decrease in volumetric shrinkage at the time of curing, a decrease in an amount of gas generated at the time of curing or heating, improvement of mechanical strength, and control of thermal conductivity or fluidity, and is considerably effective in maintaining a stable output under various environments in the present disclosure.

Regarding the output characteristics or the durability of the photoelectric conversion element, not only an influence caused by moisture or oxygen entering the photoelectric conversion element from an external environment but also an influence caused by gas generated at the time of heating and curing the sealing member cannot be ignored.

Particularly, an influence caused by the gas generated at the time of heating greatly affects the output characteristics even when the photoelectric conversion element is used under a high temperature environment.

In this case, when the filler, the gap agent, and the drying agent are included in the sealing member, they can prevent entry of moisture or oxygen, and can decrease an amount of the sealing member used, which makes it possible to obtain an effect of decreasing generation of gas. This is effective not only at the time of curing but also when the photoelectric conversion element is used under a high temperature environment.

The filler is not particularly limited and known products may be used. Preferable examples thereof include inorganic fillers such as crystalline or amorphous silica, talc, alumina, aluminum nitride, silicon nitride, calcium silicate, and calcium carbonate. These may be used alone or in combination.

An average primary particle diameter of the filler is preferably 0.1 μm or more but 10 μm or less, more preferably 1 μm or more but 5 μm or less. When the average primary particle diameter of the filler is 0.1 μm or more but 10 μm or less, an effect of preventing entry of moisture or oxygen can be sufficiently achieved, an appropriate viscosity is obtained, and adhesiveness to a substrate or a defoaming property is improved. Alternatively, it is also effective in terms of control of a width of the sealing part or workability.

An amount of the filler is preferably 10 parts by mass or more but 90 parts by mass or less, more preferably 20 parts by mass or more but 70 parts by mass or less, relative to the total amount of the sealing member. When the amount of the filler is 10 parts by mass or more but 90 parts by mass or less, an effect of preventing entry of moisture or oxygen can be sufficiently obtained, an appropriate viscosity is obtained, and adhesiveness and workability are good.

The gap agent is called a gap controlling agent or a spacer agent, and can control gap of the sealing part. For example, when a sealing member is provided on a first substrate or a first electrode and a second substrate is provided thereon for sealing, gap of the sealing part matches with a size of the gap agent because the gap agent is mixed in an epoxy resin. As a result, it is possible to easily control the gap of the sealing part.

As the gap agent, known materials in the art can be used so long as it has a particulate shape and a uniform particle diameter, and has high solvent resistance and heat resistance. The particulate shape is not particularly limited, but is preferably spherical. Specific examples thereof include glass beads, silica particles, and organic resin particles. These may be used alone or in combination.

A particle diameter of the gap agent can be selected depending on gap of the sealing part to be set. The particle diameter thereof is preferably 1 am or more but 100 μm or less, more preferably 5 μm or more but 50 μm or less.

The polymerization initiator is a material that is added for the purpose of initiating polymerization using heat or light.

The thermal polymerization initiator is a compound that generates active species such as radical cations through heating. Specific examples thereof include azo compounds such as 2,2″-azobisbutyronitrile (AIBN) and peroxides such as benzoyl peroxide (BPO). Examples of the thermal cationic polymerization initiator include benzenesulfonic acid esters and alkyl sulfonium salts.

Meanwhile, as the photopolymerization initiator, a photocationic polymerization initiator is preferably used in the case of the epoxy resin. When the photocationic polymerization initiator is mixed with the epoxy resin, followed by irradiation of light, the photocationic polymerization initiator is decomposed to generate strong acid, and the acid induces polymerization of the epoxy resin. Then, curing reaction proceeds. The photocationic polymerization initiator has such effects that volumetric shrinkage during curing is low, oxygen inhibition does not occur, and storage stability is high.

Examples of the photocationic polymerization initiator include aromatic diazonium salts, aromatic iodonium salts, aromatic sulfonium salts, metallocene compounds, and silanol-aluminum complexes. Moreover, a photoacid generator having a function of generating an acid upon irradiation of light can also be used.

The photoacid generator functions as an acid for initiating cationic polymerization. Examples of the photoacid generator include onium salts such as ionic sulfonium salt-based onium salts and ionic iodonium salt-based onium salts including a cation part and an ionic part. These may be used alone or in combination.

An amount of the polymerization initiator is preferably 0.5 parts by mass or more but 10 parts by mass or less, more preferably 1 part by mass or more but 5 parts by mass or less relative to the total amount of the sealing member. The amount of the polymerization initiator satisfying 0.5 parts by mass or more but 10 parts by mass or less allows curing to proceed appropriately, can decrease the remaining uncured products, and can prevent the amount of generated gas from being excessive, which is effective.

The drying agent is also called a moisture absorbent and is a material having a function of physically or chemically adsorbing or absorbing moisture. Inclusion of the drying agent in the sealing member is effective because moisture resistance may be further improved and influence of the outgas can be decreased in some cases.

The drying agent is preferably particulate. Examples thereof include inorganic water-absorbing materials such as calcium oxide, barium oxide, magnesium oxide, magnesium sulfate, sodium sulfate, calcium chloride, silica gel, molecular sieve, and zeolite. Among them, zeolite is preferable because zeolite absorbs a large amount of moisture. These may be used alone or in combination.

The curing accelerator is also called a curing catalyst and is used for the purpose of accelerating a curing speed. The curing accelerator is mainly used for a thermosetting epoxy resin.

Examples of the curing accelerator include: tertiary amine or tertiary amine salts such as DBU (1,8-diazabicyclo(5,4,0)-undecene-7) and DBN (1,5-diazabicyclo(4,3,0)-nonene-5); imidazole-based compounds such as 1-cyanoethyl-2-ethyl-4-methylimidazole and 2-ethyl-4-methylimidazole; and phosphine or phosphonium salts such as triphenylphosphine and tetraphenylphosphonium-tetraphenyl borate. These may be used alone or in combination.

The coupling agent has an effect of enhancing a bonding force between molecules, and examples thereof include silane coupling agents. Specific examples thereof include: silane coupling agents such as 3-glycidoxypropyltrimethoxysilane, 3-glycidoxypropylmethyldimethoxysilane, 3-glycidoxypropylmethyldimethoxysilane, 2-(3,4-epoxycyclohexyl)ethyltrimethoxysilane, N-phenyl-γ-aminopropyltrimethoxysilane, N-(2-aminoethyl)3-aminopropylmethyldimethoxysilane, N-(2-aminoethyl)3-aminopropylmethyltrimethoxysilane, 3-aminopropyltriethoxysilane, 3-mercaptopropyltrimethoxysilane, vinyltrimethoxysilane, N-(2-(vinylbenzylamino)ethyl)3-aminopropyltrimethoxysilane hydrochloride, and 3-methacryloxypropyltrimethoxysilane. These may be used alone or in combination.

As the sealing member, resin compositions that are commercially available as sealing materials, seal materials, or adhesives have been known, and can be effectively used in the present disclosure. Among them, there are resin compositions that are developed and are commercially available to be used in solar cells or organic EL elements, and can be particularly effectively used in the present disclosure.

Examples of the commercially available products of the epoxy resin include product names: TB3118, TB3114, TB3124, and TB3125F (all of which are available from ThreeBond), World Rock 5910, World Rock 5920, and World Rock 8723 (all of which are available from Kyoritsu Chemical & Co., Ltd.), and WB90US(P) (available from MORESCO).

Examples of the commercially available products of the acrylic resin include product names: TB3035B and TB3035C (both of which are available from ThreeBond) and NICHIBAN UM (available from Nichiban Co., Ltd.).

These sealing members are effective in the present disclosure because they can be subjected to a heat treatment after curing by, for example, irradiation of ultraviolet rays. The heat treatment may decrease an amount of an uncured component in some cases, which is effective in decreasing an amount of outgas that affects output characteristics, in enhancing sealing performance, and in enhancing the output characteristics and its persistence.

A heat treatment temperature is not particularly limited and may be freely set depending on a sealing member to be used. The heat treatment temperature is preferably 50° C. or more but 200° C. or less, more preferably 60° C. or more but 150° C. or less, still more preferably 70° C. or more but 100° C. or less. A heat treatment time is not particularly limited and may be freely set depending on a sealing member to be used. The heat treatment time is preferably 10 minutes or more but 10 hours or less, more preferably 20 minutes or more but 5 hours or less, still more preferably 30 minutes or more but 3 hours or less.

Meanwhile, after a glass resin having a low melting temperature is coated and fired, the resin component is decomposed. Then, while the resin component is melted through, for example, infrared laser, the resultant is allowed to adhere to the grass substrate to thereby perform the sealing. At this time, the glass component having a low melting temperature is diffused inside the metal oxide layer and is physically joined, to thereby obtain high sealing performance. In addition, since the resin component vanishes, outgas as seen in ultraviolet-curing resins is not generated, which is effective in increasing the durability of the photoelectric conversion element. Generally, glass resins having a low melting temperature are commercially available as glass frit or glass paste. These can be effectively used. In the present disclosure, those having a lower melting temperature are preferable.

In the present disclosure, a sheet-shaped sealing material may be effectively used.

The sheet-shaped sealing material is a sheet on which a resin layer has been formed on a sheet in advance. As the sheet, glass or a film having high gas barrier properties may be used, and the sheet-shaped sealing material corresponds to a second substrate in the present disclosure. When the sheet-shaped sealing material is pasted on the second electrode of the photoelectric conversion element, followed by curing, the sealing member and the substrate can be formed at one time. When the resin layer is formed on the whole surface of the sheet, the “surface sealing” is achieved. However, the “frame sealing” that provides a hollow section inside the photoelectric conversion element can be achieved depending on formation patterns of the resin layer.

A position of the sealing member is not particularly limited and may be appropriately selected depending on the intended purpose, so long as the sealing member is disposed at such a position that shields at least the hole-transporting layer, preferably the electron-transporting layer, the hole-transporting layer, and the second electrode from an external environment of the photoelectric conversion element. However, in the present disclosure, the “frame sealing” that provides a hollow section is more preferable because an appropriate amount of oxygen inside the sealed part can be adjusted.

Inclusion of oxygen in the hollow section inside the sealed part makes it possible to stably maintain a function of transporting holes of the hole-transporting layer for a long period of time, which is considerably effective in improving the durability of the photoelectric conversion element. In the present disclosure, effects can be obtained so long as oxygen is included therein, but the oxygen concentration of the hollow section inside the sealed part disposed through the sealing is more preferably 5.0% by volume or more but 21.0% by volume or less, more preferably 10.0% by volume or more but 21.0% by volume or less.

The oxygen concentration of the hollow section can be controlled by performing the sealing in a glove box in which the oxygen concentration has been adjusted. The oxygen concentration can be adjusted by a method using a gas cylinder having a specific oxygen concentration or by a method using a nitrogen gas generator. The oxygen concentration in a glove box is measured using a commercially available oxygen concentration meter or oxygen monitor.

The oxygen concentration inside the hollow section formed through the sealing can be measured through, for example, an atmospheric pressure ionization mass spectrometer (API-MS). Specifically, the photoelectric conversion element is placed in a chamber filled with an inert gas, and the sealed part is opened in the chamber. Then, the gas in the chamber is subjected to quantitative analysis through API-MS, and all the components in the gas contained in the hollow section are quantified. A ratio of oxygen to a total of the all components can be calculated to determine an oxygen concentration.

Gas other than oxygen is preferably inert gas. Examples thereof include nitrogen and argon.

When the sealing is performed, the oxygen concentration and the dew point in a glove box are preferably controlled, and such a control is effective in improving the output and the durability.

The dew point is defined as a temperature at which condensation starts when water vapor-containing gas is cooled.

The dew point is not particularly limited but is preferably 0° C. or less, more preferably −20° C. or less. The lower limit thereof is preferably −50° C. or more.

A method for forming the sealing member is not particularly limited and may be appropriately selected depending on the intended purpose. Examples thereof include various methods such as the dispensing method, the wire bar method, the spin-coating method, the roller coating method, the blade coating method, the gravure coating method, the relief printing, the offset printing, the intaglio printing, the rubber plate printing, and the screen printing.

Moreover, a passivation layer may be disposed between the second electrode and the sealing member. The passivation layer is not particularly limited and may be appropriately selected depending on the intended purpose. For example, aluminum oxide, silicon nitride, and silicon oxide are preferable.

Hereinafter, a photoelectric conversion element of the present disclosure will be described with reference to drawings. However, the present disclosure is not limited thereto. The scope of the present disclosure can encompass those that are not described in the embodiments of the present disclosure regarding, for example, the number, the position, and the shape of the following constituent components.

### First Embodiment

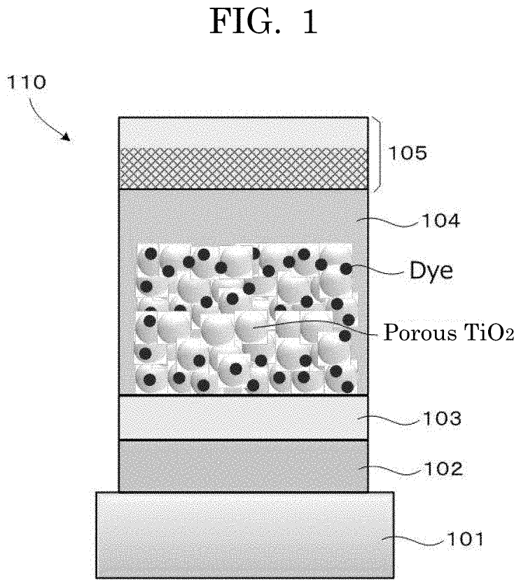

FIG. 1 is a schematic view presenting one example of a photoelectric conversion element according to the first embodiment. In a photoelectric conversion element 110 according to the first embodiment of FIG. 1, a first electrode 102 is formed on a first substrate 101, an electron-transporting layer 103 is formed on the first electrode 102, and a dye as a photosensitization compound is adsorbed on the surface of an electron-transporting material (porous TiO₂) constituting the electron-transporting layer 103. A hole-transporting layer 104 is formed on an upper part or in an inner part of the electron-transporting layer 103, and a charge-collecting layer 105 as a second electrode is formed on the hole-transporting layer 104. Although illustration of the second substrate is omitted, the second substrate is disposed on an upper part of the charge-collecting layer 105 that is the second electrode. The layers between the second substrate and the first substrate 101 are sealed with a sealing member.

In the photoelectric conversion element 110 illustrated in FIG. 1, the charge-collecting layer 105 as the second electrode includes a conductive nanowire and a conductive polymer that covers the conductive nanowire and is stacked on the hole-transporting layer. Moreover, the conductive nanowire is covered with the conductive polymer and is embedded therein. Therefore, the conductive nanowire can be prevented from being peeled from the second electrode, and thus an excellent light durability can be achieved.

Note that, each of the first electrode 102 and the charge-collecting layer 105 as the second electrode may have a path configured to allow electric current to pass to each electrode extraction terminal (not illustrated).

### Second Embodiment

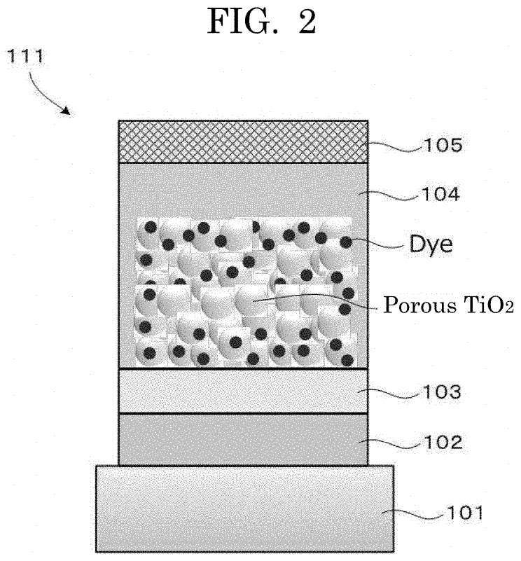

FIG. 2 is a schematic view presenting one example of a photoelectric conversion element according to the second embodiment.

A photoelectric conversion element 111 according to the second embodiment of FIG. 2 has the same configuration as that of the first embodiment except that the conductive nanowire is embedded in the conductive polymer in the charge-collecting layer 105 as the second electrode. Note that, in the second embodiment, the same reference numerals are given to the same components as those in the first embodiment that have been already described, and the description thereof is omitted.

In the photoelectric conversion element according to the second embodiment, an amount of the conductive polymer in the charge-collecting layer is small, while a rate of the contained conductive nanowire excellent in conductivity is high. Therefore, a higher conductivity can be achieved, and thus a high output can be obtained.

### Comparative Embodiment

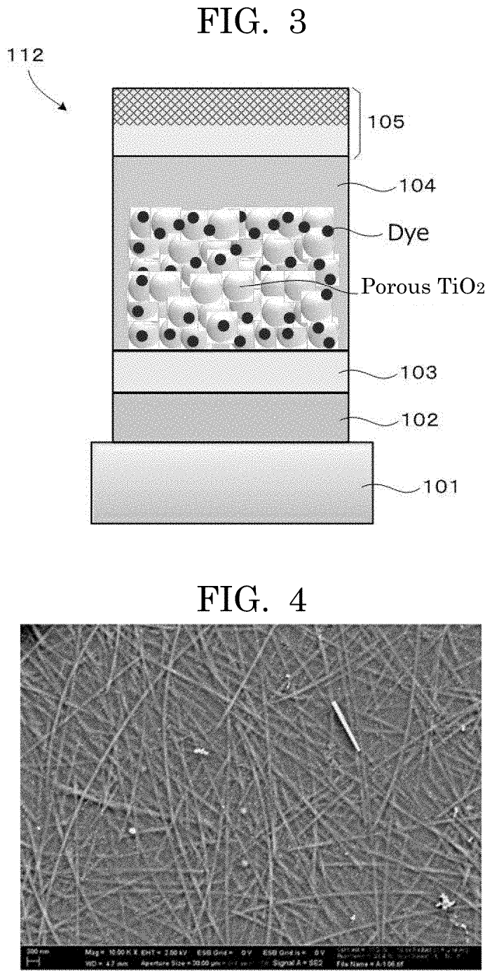

FIG. 3 is a schematic view presenting one example of a photoelectric conversion element according to the comparative embodiment.

A photoelectric conversion element 112 according to the comparative embodiment of FIG. 3 has the same configuration as that of the first embodiment except that the conductive nanowire is not covered with the conductive polymer, and a layer formed of the conductive nanowire and a layer formed of the conductive polymer are separated from each other, in the charge-collecting layer 105 as the second electrode. Note that, in the comparative embodiment, the same reference numerals are given to the same components as those in the first embodiment that have been already described, and the description thereof is omitted.

The photoelectric conversion element according to the comparative embodiment was not successfully formed because the film formation of the conductive nanowire in the charge-collecting layer was bad, and the charge-collecting layer could not function sufficiently.

A photoelectric conversion module of the present disclosure can be applied to, for example, a power supply device by combining it with a circuit board configured to control generated electric current. Examples of devices using the power supply device include electronic desk calculators and watches. Moreover, the power supply device including the photoelectric conversion module of the present disclosure can be applied to, for example, mobile phones, electronic organizers, and electronic paper. By combining the photoelectric conversion module with, for example, an auxiliary power supply for prolonging a continuous operating time of a charge-type or dry cell-type electronic equipment, or a secondary cell, the power supply device including the photoelectric conversion module of the present disclosure can be used as a power supply that can be used at night. Furthermore, it can be used for internet of things (IoT) devices or artificial satellites as a self-supporting power supply that does not require that does not require replacement of a cell or wiring of a power supply.

### (Electronic Device)

An electronic device of the present disclosure includes the photoelectric conversion module of the present disclosure, and a device configured to be driven by electric power generated through photoelectric conversion of the photoelectric conversion module, and further includes other devices if necessary.

### (Power Supply Module)

A power supply module of the present disclosure includes the photoelectric conversion module of the present disclosure and a power supply integrated circuit (IC), and further includes other devices if necessary.

Next, a specific embodiment of an electronic device including the photoelectric conversion module of the present disclosure, and a device configured to be driven by electric power obtained through power generation of the photoelectric conversion module will be described.

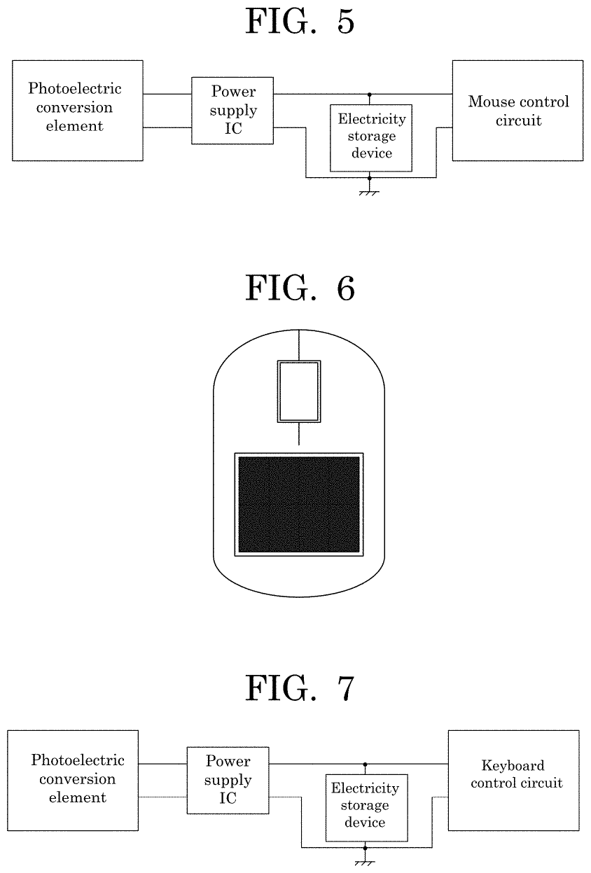

FIG. 5 is a block diagram of a mouse for a personal computer as one example of an electronic device of the present disclosure.

As presented in FIG. 5, a photoelectric conversion module, a power supply IC, and an electricity storage device are combined, and the supplied electric power is allowed to pass to a power supply of a control circuit of a mouse. As a result, the electricity storage device is charged when the mouse is not used, and the mouse can be driven by the electric power, and therefore such a mouse that does not require wiring or replacement of a cell can be obtained. Because a cell is not required, a weight thereof can be decreased, which is effective.

FIG. 6 is a schematic external view presenting one example of the mouse presented in FIG. 5.

As presented in FIG. 6, a photoelectric conversion module, a power supply IC, and an electricity storage device are mounted inside a mouse, but an upper part of a photoelectric conversion element is covered with a transparent housing so that the photoelectric conversion element of the photoelectric conversion module receives light. Moreover, the whole housing of the mouse can be formed of a transparent resin. The arrangement of the photoelectric conversion element is not limited to the above. For example, the photoelectric conversion element may be arranged in a position to which light is applied even when the mouse is covered with a hand, and such arrangement may be preferable.

Next, another embodiment of an electronic device including the photoelectric conversion module of the present disclosure, and a device configured to be driven by electric power obtained through power generation of the photoelectric conversion module will be described.

FIG. 7 is a block diagram of a keyboard for a personal computer as one example of an electronic device of the present disclosure.

As presented in FIG. 7, a photoelectric conversion element of a photoelectric conversion module, a power supply IC, and an electricity storage device are combined, and the supplied electric power is allowed to pass to a power supply of a control circuit of a keyboard. As a result, the electricity storage device is charged when the keyboard is not used, and the keyboard can be driven by the electric power. Therefore, such a keyboard that does not require wiring or replacement of a cell can be obtained. Since a cell is not required, a weight thereof can be decreased, which is effective.

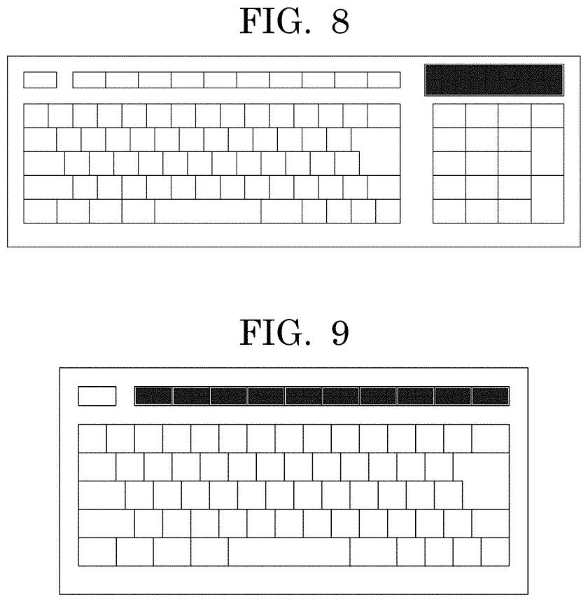

FIG. 8 is a schematic external view presenting one example of the keyboard presented in FIG. 7.

As presented in FIG. 8, a photoelectric conversion element of a photoelectric conversion module, a power supply IC, and an electricity storage device are mounted inside the keyboard, but an upper part of the photoelectric conversion element is covered with a transparent housing so that the photoelectric conversion element receives light. The whole housing of the keyboard can be formed of a transparent resin. The arrangement of the photoelectric conversion element is not limited to the above. In the case of a small keyboard in which a space for incorporating the photoelectric conversion element is small, a small photoelectric conversion element may be embedded in some keys as presented in FIG. 9, and such arrangement is effective.

Next, another embodiment of an electronic device including the photoelectric conversion module of the present disclosure, and a device configured to be driven by electric power obtained through power generation of the photoelectric conversion module will be described.

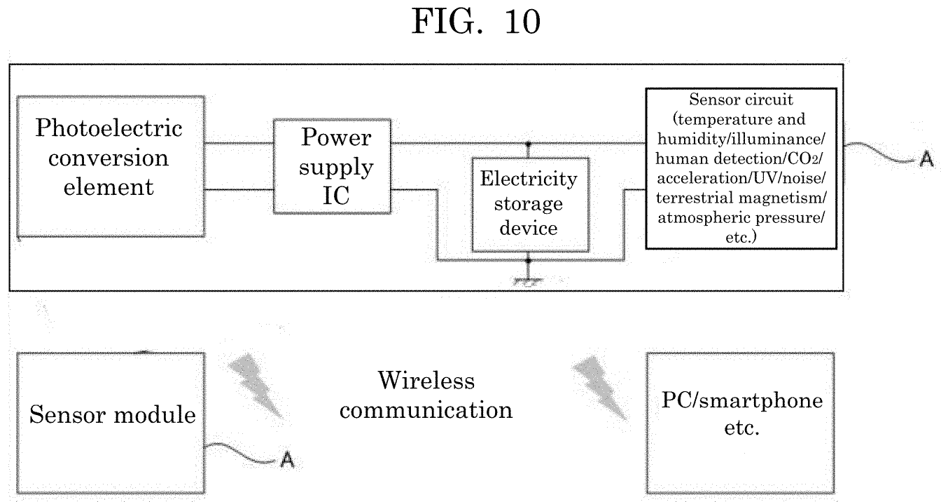

FIG. 10 is a block diagram of a sensor as one example of an electronic device of the present disclosure.

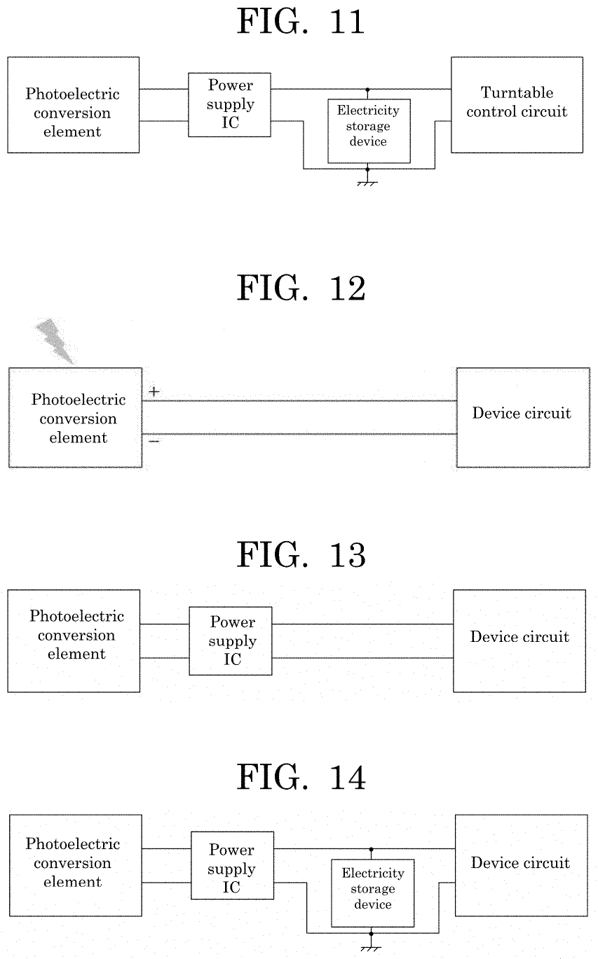

As presented in FIG. 10, a photoelectric conversion element of a photoelectric conversion module, a power supply IC, and an electricity storage device are combined, and the supplied electric power is allowed to pass to a power supply of a sensor circuit. As a result, a sensor module can be constituted without requiring connection to an external power supply and replacement of a cell. A sensing target is, for example, temperature and humidity, illuminance, human detection, CO₂, acceleration, ultraviolet rays (UV), noise, terrestrial magnetism, and atmospheric pressure, and such an electronic device can be applied to various sensors, which is effective. As presented in FIG. 11, the sensor module is configured to sense a target to be measured on a regular basis and to transmit the read data to a personal computer (PC) or a smartphone through wireless communication.

It is expected that use of sensors is significantly increased as the internet of things (IoT) society approaches. Replacing batteries of numerous sensors one by one is time consuming and is not realistic. Moreover, the fact that a sensor is installed at a position such as a ceiling and a wall where a cell is not easily replaced also makes workability bad. Moreover, supplying electric power by the photoelectric conversion element is also a significantly large advantage. In addition, the photoelectric conversion module of the present disclosure has advantages that a high output can be obtained even with light of a low illuminance and a high degree of freedom in installation can be achieved because dependence of light incident angle for the output is small.

Another embodiment of an electronic device including the photoelectric conversion module of the present disclosure and a device configured to be driven by electric power obtained through power generation of the photoelectric conversion element module will be described.

FIG. 11 is a block diagram of a turntable as one example of an electronic device of the present disclosure.

As presented in FIG. 11, a photoelectric conversion element, a power supply IC, and an electricity storage device are combined, and the supplied electric power is allowed to pass to a power supply of a turntable circuit. As a result, the turntable can be constituted without requiring connection to an external power supply and replacement of a cell. The turntable is used, for example, in a display case in which products are displayed. Wiring of a power supply degrades appearance of the display, and moreover displayed products need to be removed at the time of replacing a cell, which is time-consuming. Use of the photoelectric conversion module of the present disclosure is effective because the aforementioned problems can be solved.

As described above, the electronic device including the photoelectric conversion module of the present disclosure and the device configured to be driven by electric power obtained through power generation of the photoelectric conversion module, and the power supply module have been described above. However, the described embodiments are only part of applicable embodiments, and use of the photoelectric conversion module of the present disclosure is not limited to the above-described uses.

### <Use>

The photoelectric conversion module of the present disclosure can function as a self-sustaining power supply, and electric power generated through photoelectric conversion can be used to drive a device. Since the photoelectric conversion module of the present disclosure can generate electricity by irradiation of light, it is not necessary to couple the electronic device to a power supply or to replace a cell. Therefore, the electronic device can be driven in a place where there is no power supply facility, the electronic device can be worn or carried, and the electronic device can be driven without replacement of a cell even in a place where a cell is not easily replaced. Moreover, when a dry cell is used, the electronic device becomes heavy by a weight of the dry cell, or the electronic device becomes large by a size of the dry cell. Therefore, there may be a problem in installing the electronic device on a wall or ceiling, or transporting the electronic device. Since the photoelectric conversion module of the present disclosure is light and thin, it can be freely installed, and can be worn and carried, which is advantageous.

As described above, the photoelectric conversion module of the present disclosure can be used as a self-sustaining power supply, and can be combined with various electronic devices. For example, the photoelectric conversion module of the present disclosure can be used in combination with a display device (e.g., an electronic desk calculator, a watch, a mobile phone, an electronic organizer, and electronic paper), an accessory device of a personal computer (e.g., a mouse and a keyboard), various sensor devices (e.g., a temperature and humidity sensor and a human detection sensor), transmitters (e.g., a beacon and a global positioning system (GPS)), and numerous electronic devices (e.g., an auxiliary lamp and a remote controller).

The photoelectric conversion module of the present disclosure is widely applied because it can generate electricity particularly with light of a low illuminance and can generate electricity indoors and in further darker shade. Moreover, the photoelectric conversion module is highly safe because liquid leakage found in the case of a dry cell does not occur, and accidental ingestion found in the case of a button cell does not occur. Furthermore, the photoelectric conversion module can be used as an auxiliary power supply for the purpose of prolonging a continuous operation time of a charge-type or dry cell-type electronic equipment. As described above, when the photoelectric conversion module of the present disclosure is combined with a device configured to be driven by electric power generated through photoelectric conversion of the photoelectric conversion module, it is possible to obtain such an electronic device that is light and easy to use, has a high degree of freedom in installation, does not require replacement of a cell, is excellent in safety, and is effective in decreasing environmental loads.

FIG. 12 presents a basic configuration diagram of an electronic device obtained by combining the photoelectric conversion module of the present disclosure with a device configured to be driven by electric power generated through photoelectric conversion of the photoelectric conversion module. The electronic device can generate electricity when the photoelectric conversion element is irradiated with light, and can extract electric power. A circuit of the device can be driven by the generated electric power.

Since the output of the photoelectric conversion element of the photoelectric conversion module varies depending on circumferential illuminance, the electronic device presented in FIG. 12 may not be stably driven in some cases. In this case, as presented in FIG. 13, a power supply IC for a photoelectric conversion element can be incorporated between the photoelectric conversion element and the circuit of the device in order to supply stable voltage to a side of the circuit, and such arrangement is effective.

The photoelectric conversion element of the photoelectric conversion module can generate electricity so long as light of a sufficient illuminance is applied thereto. However, when an illuminance for generating electricity is not enough, desired electric power cannot be obtained, which is a disadvantage of the photoelectric conversion element. In this case, as presented in FIG. 14, when an electricity storage device such as a capacitor is mounted between a power supply IC and a device circuit, excess electric power from the photoelectric conversion element can be stored in the electricity storage device. In addition, the electric power stored in the electricity storage device can be supplied to a device circuit to thereby enable stable operation when the illuminance is too low or even when light is not applied to the photoelectric conversion element.

As described above, the electronic device obtained by combining the photoelectric conversion module of the present disclosure with the device circuit can be driven even in an environment without a power supply, does not require replacement of a cell, and can be stably driven in combination with a power supply IC or an electricity storage device. Therefore, it is possible to make the most of advantages of the photoelectric conversion element.

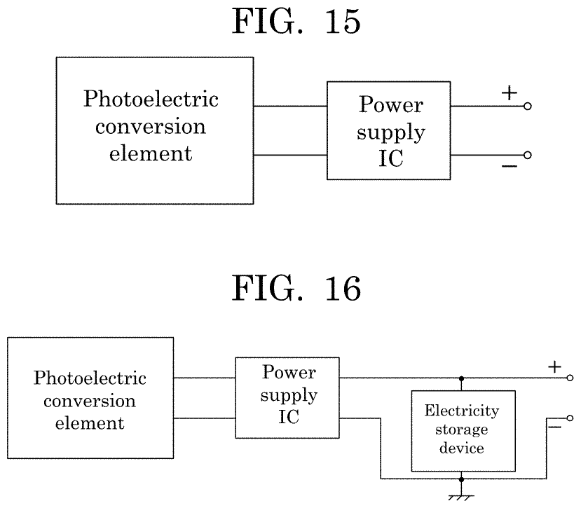

Meanwhile, the photoelectric conversion module of the present disclosure can also be used as a power supply module, and such use is effective. As presented in FIG. 15, for example, when the photoelectric conversion module of the present disclosure is coupled to a power supply IC for a photoelectric conversion element, it is possible to constitute a DC power supply module, which can supply electric power generated through photoelectric conversion of the photoelectric conversion element of the photoelectric conversion module to the power supply IC at a predetermined voltage level.

Moreover, as presented in FIG. 16, when an electricity storage device is added to a power supply IC, electric power generated by the photoelectric conversion element of the photoelectric conversion module can be stored in the electricity storage device. Therefore, a power supply module to which electric power can be supplied can be constituted when the illuminance is too low or even when light is not applied to the photoelectric conversion element.

The power supply modules of the present disclosure presented in FIG. 15 and FIG. 16 can be used as a power supply module without replacement of a cell as in case of conventional primary cells.

### EXAMPLES

Hereinafter, the present disclosure will be described by way of Examples and Comparative Examples. However, the present disclosure should not be construed as being limited to Examples exemplified herein.

### Reference Example 1

### <Production of Photoelectric Conversion Element>

On a glass substrate as a first substrate, a film of indium-doped tin oxide (ITO) and a film of niobium-doped tin oxide (NTO) as a first electrode were sequentially formed through sputtering. Then, a compact layer formed of titanium oxide as a hole blocking layer was formed through reactive sputtering with oxygen gas.

Next, titanium oxide (ST-21, obtained from ISHIHARA SANGYO KAISHA, LTD.) (3 parts by mass), acetylacetone (0.2 parts by mass), and polyoxyethylene octylphenyl ether (obtained from Wako Pure Chemical Industries, Ltd.) (0.3 parts by mass) as a surfactant were subjected to a bead mill treatment for 12 hours together with water (5.5 parts by mass) and ethanol (1.0 part by mass). To the titanium oxide dispersion liquid obtained, polyethylene glycol (polyethylene glycol 20,000, obtained from Wako Pure Chemical Industries, Ltd.) (1.2 parts by mass) was added, to thereby prepare paste.

The paste prepared was coated on the hole blocking layer (average thickness: about 1.2 μm) and was dried at 100° C. Then, the resultant was fired at 550° C. for 30 minutes in the air, to thereby form a porous electron-transporting layer.

The glass substrate on which the electron-transporting layer had been formed was immersed in a mixed solution including a photosensitization compound expressed by the B-5 and acetonitrile/t-butanol (volume ratio: 1:1) and was left to stand for 1 hour in the dark. Then, the excess photosensitization compound was removed, and the photosensitization compound was adsorbed on the surface of the electron-transporting layer.

To chlorobenzene (1,550 parts by mass), lithium bis(trifluoromethanesulfonyl)imide (LiTFSI) as a lithium salt (obtained from KANTO CHEMICAL CO., INC.) (30 parts by mass), a compound including a pyridine ring structure expressed by the C-10 (55 parts by mass), a hole-transporting material expressed by the D-7 (obtained from Merck KGaA) (273 parts by mass), a cobalt complex expressed by the F-11 as an oxidizing agent (obtained from Sigma-Aldrich Japan) (26 parts by mass), and acetonitrile (obtained from KANTO CHEMICAL CO., INC.) (80 parts by mass) were added, followed by dissolving, to prepare a coating liquid for a hole-transporting layer.

Next, on the electron-transporting layer to which the photosensitization compound had been adsorbed, a hole-transporting layer was formed (average thickness: about 500 nm) through the die coating method using the coating liquid for the hole-transporting layer. Then, the hole-transporting layer coated on the peripheral portions of the glass substrate was removed. On the hole-transporting layer, silver was deposited under vacuum to thereby form a second electrode (average thickness: 100 nm).

On the peripheral portions of the glass substrate from which the hole-transporting layer had been removed, an ultraviolet-curing resin (World Rock No. 5910, obtained from Kyoritsu Chemical & Co., Ltd.) as a sealing member was coated using a dispenser (2300N, obtained from SAN-EI TECH LTD.) so as to surround a power generation region. Then, it was transferred to a glove box into which high purity air (dew point: −50° C.) had been introduced, and a cover glass as a second substrate was placed on the ultraviolet-curing resin. Then, the resin was cured by irradiation of ultraviolet rays to seal the power generation region. The resultant was finally subjected to a heat treatment at 80° C. for 1 hour, to produce a photoelectric conversion element of Reference Example 1.

### Example 1

A photoelectric conversion element of Example 1 having a layer configuration presented in FIG. 1 was produced in the same manner as in Reference Example 1 except that the volume ratio of Reference Example 1 was changed to the volume ratio in second electrode (charge-collecting layer) presented in Table 1 to form a second electrode as described below. FIG. 4 presents a SEM photograph of the surface of the second electrode of Example 1.

### <Production Method of Second Electrode (Charge-Collecting Layer)>

A dispersion liquid of silver nanowire having a diameter of 60 nm and a length of 10 μm (obtained from Aldrich) was coated through die coating to form a film (70 nm), and the resultant was heated and dried at 120° C. for 5 minutes. Then, a film of polyaniline (emeraldine base) (obtained from Aldrich) was formed through die coating, and was heated and dried at 100° C. for 30 minutes.

### Examples 2 and 3

A photoelectric conversion element was produced in the same manner as in Example 1 except that the volume ratio of Example 1 was changed to each volume ratio in second electrode (charge-collecting layer) presented in Table 1 to form a charge-collecting layer.

### Examples 4 to 6

A photoelectric conversion element was produced in the same manner as in Example 1 except that the conductive polymer was changed to PEDOT/PSS (polythiophene, Orgacon S315, obtained from Aldrich), and the volume ratio of Example 1 was changed to the volume ratio in second electrode (charge-collecting layer) presented in Table 1 to form a charge-collecting layer.

### Comparative Examples 1 and 2

A photoelectric conversion element was produced in the same manner as in Example 1 except that the second electrode (charge-collecting layer) was changed as described in Table 1 to form a charge-collecting layer.

### Comparative Example 3

A photoelectric conversion element of Example 3 having a layer configuration presented in FIG. 3 was produced in the same manner as in Example 1 except that a conductive polymer layer was formed on the hole-transporting layer and a silver nanowire layer was formed on the conductive polymer layer.

Next, the characteristics of the photoelectric conversion elements of Reference Example 1, Examples 1 to 6, and Comparative Examples 1 to 3 were evaluated in the following manners. Results are presented in Table 1.

### <Transmittance of Second Electrode>

The second electrode layer coated on the glass substrate under the same film formation conditions was measured for the transmittance using an ultraviolet and visible spectrophotometer (UV-2600/2700, obtained from SHIMADZU CORPORATION).

### <Output Characteristics and Durability Test of Photoelectric Conversion Element>

Using a solar cell test system (As-510-PV03, obtained from NF CORPORATION), under irradiation of white LED (obtained from TOSHIBA CORPORATION) (5,000 K) of which illuminance had been adjusted to 200 lux, each of the produced photoelectric conversion elements was evaluated for IV characteristics. An initial maximum output power Pmax 1 (μW/cm²) thereof was determined.

Next, for 1,000 hours, the photoelectric conversion element was irradiated with white LED of which illuminance had been adjusted to 8,000 lux. Then, the photoelectric conversion element was evaluated again for IV characteristics under irradiation of white LED of which illuminance had been adjusted to 200 lux, and a maximum output power Pmax 2 (μW/cm²) after the test was determined.

Finally, the maximum output power Pmax 2 (W/cm²) after the test was divided by the initial maximum output power Pmax 1 (μW/cm²) to thereby determine a Pmax maintenance rate (Pmax 2/Pmax 1×100) after the durability test.

TABLE 1

| | Volume ratio in | | | | |
|---|---|---|---|---|---|
| | second electrode | | | | |
| | (charge-collecting layer) | | | Initial | Pmax |
| | Silver | Conductive | Transmittance | Pmax | maintenance |
| | nanowire | polymer | (%) | (μW/cm²) | rate (%) |
| Reference | Silver deposition | | 8 | 9.2 | 85 |
| Example 1 | | | | | |
| Example 1 | 1 | 1 | 86 | 8.9 | 87 |
| Example 2 | 1 | 4 | 82 | 8.7 | 85 |
| Example 3 | 1 | 5 | 77 | 7.2 | 76 |
| Example 4 | 1 | 1 | 88 | 8.6 | 85 |
| Example 5 | 1 | 4 | 83 | 8.4 | 83 |
| Example 6 | 1 | 5 | 79 | 7.1 | 78 |
| Comparative | Presence | Absence | 89 | 4.2 | 54 |
| Example 1 | | | | | |
| Comparative | Absence | Presence | 93 | 2.9 | 35 |
| Example 2 | | | | | |
| Comparative | 1 | 1 | 85 | 6.1 | 38 |
| Example 3 | | | | | |

Aspects of the present disclosure are as follows, for example.

<1> A photoelectric conversion element including:

a first electrode;

an electron-transporting layer;

a hole-transporting layer; and

a second electrode,

the electron-transporting layer, the hole-transporting layer, and the second electrode being on or above the first electrode,

wherein the second electrode includes a charge-collecting layer, where the charge-collecting layer includes a conductive nanowire and a conductive polymer that covers at least part of the conductive nanowire and is stacked on the hole-transporting layer.

<2> The photoelectric conversion element according to <1>, wherein the conductive nanowire is a silver nanowire.
<3> The photoelectric conversion element according to <1> or <2>, wherein, in the charge-collecting layer, the at least part of the conductive nanowire is embedded in the conductive polymer.
<4> The photoelectric conversion element according to any one of <1> to <3>, wherein the second electrode has translucency.
<5> The photoelectric conversion element according to any one of <1> to <3>,

wherein a volume ratio between the conductive nanowire in the charge-collecting layer and the conductive polymer in the charge-collecting layer (the conductive nanowire: the conductive polymer) is from 1:1 through 1:4.

<6> The photoelectric conversion element according to any one of <1> to <5>,

wherein the electron-transporting layer includes a porous titanium oxide particle.

<7> The photoelectric conversion element according to any one of <1> to <6>,

wherein the conductive polymer includes polythiophene, polyaniline, polypyrrole, or a derivative of foregoing.

<8> A photoelectric conversion module including

photoelectric conversion elements that are electrically coupled in series or in parallel, each of the photoelectric conversion elements is the photoelectric conversion element according to any one of <1> to <7>.

<9> An electronic device including:

the photoelectric conversion module according to <8>; and

a device configured to be driven by electric power generated through photoelectric conversion of the photoelectric conversion module.

<10> An electronic device including:

the photoelectric conversion module according to <8>;

an electricity storage device configured to store electric power generated through photoelectric conversion of the photoelectric conversion module; and

a device configured to be driven by at least one selected from the group consisting of the electric power generated through photoelectric conversion of the photoelectric conversion module and the electric power stored in the electricity storage device.

<11> A power supply module including:

the photoelectric conversion module according to <8>; and

a power supply integrated circuit.

The photoelectric conversion element according to any one of <1> to <7>, the photoelectric conversion module according to <8>, the electronic device according to <9> or <10>, and the power supply module according to <11> can solve the existing problems in the art and can achieve the object of the present disclosure.

What is claimed is:

1. A photoelectric conversion element comprising:
a first electrode;
an electron-transporting layer;
a hole-transporting layer; and
a second electrode,
the electron-transporting layer, the hole-transporting layer, and the second electrode are on or above the first electrode,
wherein the second electrode includes a charge-collecting layer, where the charge-collecting layer includes a conductive nanowire and a conductive polymer that covers at least part of the conductive nanowire and is stacked on the hole-transporting layer.

2. The photoelectric conversion element according to claim 1,
wherein the conductive nanowire is a silver nanowire.

3. The photoelectric conversion element according to claim 1,
wherein, in the charge-collecting layer, the at least part of the conductive nanowire is embedded in the conductive polymer.

4. The photoelectric conversion element according to claim 1,
wherein the second electrode has translucency.

5. The photoelectric conversion element according to claim 1,
wherein a volume ratio between the conductive nanowire in the charge-collecting layer and the conductive polymer in the charge-collecting layer (the conductive nanowire: the conductive polymer) is from 1:1 through 1:4.

6. The photoelectric conversion element according to claim 1,
wherein the electron-transporting layer includes a porous titanium oxide particle.

7. The photoelectric conversion element according to claim 1,
wherein the conductive polymer includes polythiophene, polyaniline, polypyrrole, or a derivative of foregoing.

8. A photoelectric conversion module comprising
photoelectric conversion elements that are electrically coupled in series or in parallel, each of the photoelectric conversion elements is the photoelectric conversion element according to claim 1.

9. An electronic device comprising:
the photoelectric conversion module according to claim 8; and
a device configured to be driven by electric power generated through photoelectric conversion of the photoelectric conversion module.

10. An electronic device comprising:
the photoelectric conversion module according to claim 8;
an electricity storage device configured to store electric power generated through photoelectric conversion of the photoelectric conversion module; and
a device configured to be driven by at least one selected from the group consisting of the electric power generated through photoelectric conversion of the photoelectric conversion module and the electric power stored in the electricity storage device.

11. A power supply module comprising:
the photoelectric conversion module according to claim 8; and
a power supply integrated circuit.
